(19) United States
(12) Patent Application Publication
(10) Pub. No.: US 2024/0204156 A1
(43) Pub. Date: Jun. 20, 2024

(54) DISPLAY DEVICE AND METHOD OF MANUFACTURING THE SAME

(71) Applicant: Samsung Display Co., LTD., Yongin-si (KR)

(72) Inventor: INYOUNG JUNG, Yongin-si (KR)

(73) Assignee: Samsung Display Co., LTD., Yongin-si (KR)

(21) Appl. No.: 18/474,303

(22) Filed: Sep. 26, 2023

(30) Foreign Application Priority Data
Dec. 20, 2022 (KR) 10-2022-0179227

(51) Int. Cl. H01L 33/62; H01L 25/075

(52) U.S. Cl. CPC H01L 33/62; H01L 25/0753; H01L 2933/0016; H01L 2933/0066

(57) ABSTRACT

A display device includes a first area including a transmission area and a non-transmission area adjacent to the transmission area and a second area adjacent to the first area, a circuit element layer disposed in the second area on a substrate, a light emitting element layer disposed on the circuit element layer, electrically connected to the circuit element layer, and including first light emitting diodes disposed in the non-transmission area, and an organic layer disposed on the circuit element layer, adjacent to the light emitting element layer, and including an opening overlapping the transmission area in a plan view and between the first light emitting diodes.

### CROSS-REFERENCE TO RELATED APPLICATION(S)

This application claims priority to and benefits of Korean Patent Application No. 10-2022-0179227 under 35 U.S.C. § 119, filed on Dec. 20, 2022 in the Korean Intellectual Property Office, the entire contents of which are incorporated herein by reference.

### BACKGROUND

### 1. Technical Field

Embodiments generally relate to a display device. Embodiments relate to a display device and a method of manufacturing the same.

### 2. Description of the Related Art

A display device may provide visual information to a user by displaying an image. To this end, the display device may include a display panel that converts electrical signals into images. The display panel may include a transmission area that transmits external light incident on the display device. An electronic module disposed on a rear surface of the display panel may detect or recognize an object, a user, or the like located on a front surface of the display panel through the transmission area.

In case that an organic layer is disposed in the transmission area, the organic layer may reflect or absorb light in the transmission area and reduce transmittance.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device with improved display quality.

Embodiments provide a method of manufacturing the display device.

The technical objectives to be achieved by the disclosure are not limited to those described herein, and other technical objectives that are not mentioned herein would be clearly understood by a person skilled in the art from the description of the disclosure.

A display device according to embodiments may include a first area including a transmission area and a non-transmission area adjacent to the transmission area and a second area adjacent to the first area; a circuit element layer disposed in the second area on a substrate; a light emitting element layer disposed on the circuit element layer, electrically connected to the circuit element layer, and including first light emitting diodes disposed in the non-transmission area, and an organic layer disposed on the circuit element layer, adjacent to the light emitting element layer, and including an opening overlapping the transmission area in a plan view and between the first light emitting diodes.

In an embodiment, the opening of the organic layer may be spaced apart from the first light emitting diodes in a plan view.

In an embodiment, the organic layer may include a first organic film disposed between the circuit element layer and the light emitting element layer, overlapping the second area and the non-transmission area in a plan view, and including a first opening overlapping the transmission area in a plan view, and a second organic film disposed on the first organic film, overlapping the second area and the non-transmission area in a plan view, and including a second opening overlapping the transmission area in a plan view. The first opening and the second opening may overlap in a plan view. The first opening and the second opening may constitute the opening of the organic layer.

In an embodiment, the first organic film may overlap the first light emitting diodes in a plan view. The second organic film may be adjacent to the first light emitting diodes.

In an embodiment, the display device may further include a connection line electrically connecting the circuit element layer and each of the first light emitting diodes and a sub-organic film covering the connection line in the transmission area.

In an embodiment, a height of the sub-organic film may be less than a sum of a height of the first organic film and a height of the second organic film.

In an embodiment, the sub-organic film and the first organic film may include a same material. A height of the sub-organic film may be less than a height of the first organic film.

In an embodiment, the sub-organic film the second organic film may include a same material. A height of the sub-organic film may be less than a height of the second organic film.

In an embodiment, the light emitting element layer may further include second light emitting diodes disposed on the circuit element layer and disposed in the second area.

In an embodiment, each of the first light emitting diodes may include a pixel electrode and a light emitting layer disposed on the pixel electrode.

In an embodiment, the first organic film may be disposed below the pixel electrode and overlaps the pixel electrode in a plan view, the second organic film may include a pixel opening exposing a portion of the pixel electrode, and the light emitting layer is disposed in the pixel opening.

A display device according to embodiments may include a first area including a transmission area and a non-transmission area adjacent to the transmission area and a second area adjacent to the first area; a circuit element layer disposed in the non-transmission area on a substrate; a light emitting element layer disposed on the circuit element layer, electrically connected to the circuit element layer, and including light emitting diodes disposed in the non-transmission area; and an organic layer disposed on the circuit element layer, adjacent to the light emitting element layer, and including an opening overlapping the transmission area in a plan view and between the light emitting diodes.

In an embodiment, the opening of the organic layer may not overlap the light emitting diodes in a plan view.

In an embodiment, the organic layer may include a first organic film disposed between the circuit element layer and the light emitting element layer, overlapping the second area and the non-transmission area in a plan view, and including a first opening overlapping the transmission area in a plan view, and a second organic film disposed on the first organic film, overlapping the second area and the non-transmission area in a plan view, and including a second opening overlapping the transmission area in a plan view.

In an embodiment, the first organic film may overlap the light emitting diodes in a plan view. The second organic film may be adjacent to the light emitting diodes.

A method of manufacturing a display device according to embodiments may include forming a circuit element layer in a second area on a substrate including a first area including a transmission area and a non-transmission area adjacent to the transmission area, and the second area having a lower transmittance than a transmittance of the first area; forming an organic layer on the circuit element layer; forming a light emitting element layer including first light emitting diodes in the non-transmission area on the circuit element layer; and forming an opening formed between the first light emitting diodes in the transmission area by patterning the organic layer.

In an embodiment, the forming of the light emitting element layer and the forming of the organic layer may include forming a first organic film on the circuit element layer; forming a first opening overlapping the transmission area in the first organic film in a plan view; forming a pixel electrode on the first organic film; forming a second organic film on the pixel electrode; forming a second opening overlapping the transmission area in a plan view and a pixel opening exposing a portion of the pixel electrode in the second organic film; and forming a light emitting layer in the pixel opening.

In an embodiment, the method may further include forming a connection line electrically connected to the circuit element layer and the pixel electrode.

In an embodiment, the method may further include forming a sub-organic film overlapping the connection line in a plan view by patterning the first organic film.

In an embodiment, the forming of the sub-organic film may be performed simultaneously with the forming of the first organic film. A height of the sub-organic film may be less than a height of the first organic film.

In an embodiment, the sub-organic film and the first organic film may be formed by using a halftone mask.

In an embodiment, the method may further include forming a sub-organic film overlapping the connection line in a plan view by patterning the second organic film.

In an embodiment, the forming of the sub-organic film may be performed simultaneously with the forming of the second organic film. A height of the sub-organic film may be less than a height of the second organic film.

In an embodiment, the sub-organic film and the second organic film may be formed by using a halftone mask.

In a display device according to embodiments since the display device may include an organic layer including an opening overlapping a transmission area in a plan view, transmittance in a first area of the display device may be improved. For example, since the organic layer is not disposed in the transmission area, reflection and absorption of light due to the organic layer may be minimized. Accordingly, the display quality of the display device may be improved.

By further disposing the sub-organic film on connecting lines disposed in the transmission area, unnecessary light emission due to the connecting lines may be prevented. Accordingly, the display quality of the display device may be improved.

### BRIEF DESCRIPTION OF THE DRAWINGS

Illustrative, non-limiting embodiments will be more clearly understood from the following detailed description in conjunction with the accompanying drawings in which:

FIG. 1 is a view illustrating a display device according to an embodiment.

FIG. 2 is a schematic cross-sectional view illustrating a display module included in the display device of FIG. 1.

FIG. 3 is a schematic plan view illustrating a display panel included in the display module of FIG. 2.

FIG. 4 is an enlarged view illustrating an enlarged area ‘A’ of FIG. 3.

FIG. 5 is a schematic cross-sectional view illustrating a portion of each of an auxiliary display areas included in a first area and a second area of the display panel of FIG. 3.

FIG. 6 is a schematic cross-sectional view illustrating another portion of each of an auxiliary display areas included in a first area and a second area of the display panel of FIG. 3.

FIG. 7 is a schematic cross-sectional view illustrating another example of FIG. 6.

FIG. 8 is a schematic plan view illustrating another example of a display panel included in the display device of FIG. 1.

FIG. 9 is a schematic plan view illustrating an example of a first area included in the display panel of FIG. 8.

FIG. 10 is a schematic cross-sectional view taken along line II-II′ of FIG. 9.

FIGS. 11, 12, 13, 14, 15, 16, 17, 18, 19, 20, and 21 are views illustrating a method of manufacturing a display device according to an embodiment.

FIGS. 22, 23, and 24 are views illustrating a method of manufacturing another portion of a display device according to an embodiment.

FIGS. 25 and 26 are views illustrating other examples of FIGS. 22, 23, and 24.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In this specification, it will be understood that when an element (or region, layer, portion, etc.) is referred to as being “on”, “connected to” or “coupled to” another element, it can be directly on, connected or coupled to the other element, or intervening elements may be present.

Like reference numerals refer to like elements throughout. In the drawings, the thicknesses, ratios, and dimensions of elements are exaggerated for effective description of the technical contents.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

As used herein, the singular forms, “a,” “an,” and “the” are intended to include the plural forms as well, unless the context clearly indicates otherwise.

It will be understood that, although the terms first, second, etc. may be used herein to describe various elements, these elements should not be limited by these terms. These terms are only used to distinguish one element from another element. For example, a first element could be termed a second element without departing from the scope of the disclosure. Similarly, the second element may also be referred to as the first element.

In addition, terms, such as “below”, “lower”, “above”, “upper” and the like, are used herein for ease of description to describe one element's relation to another element(s) as illustrated in the figures. The above terms are relative concepts and are described based on the directions indicated in the drawings.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. The term “overlap” or “overlapped” means that a first object may be above or below or to a side of a second object, and vice versa.

Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

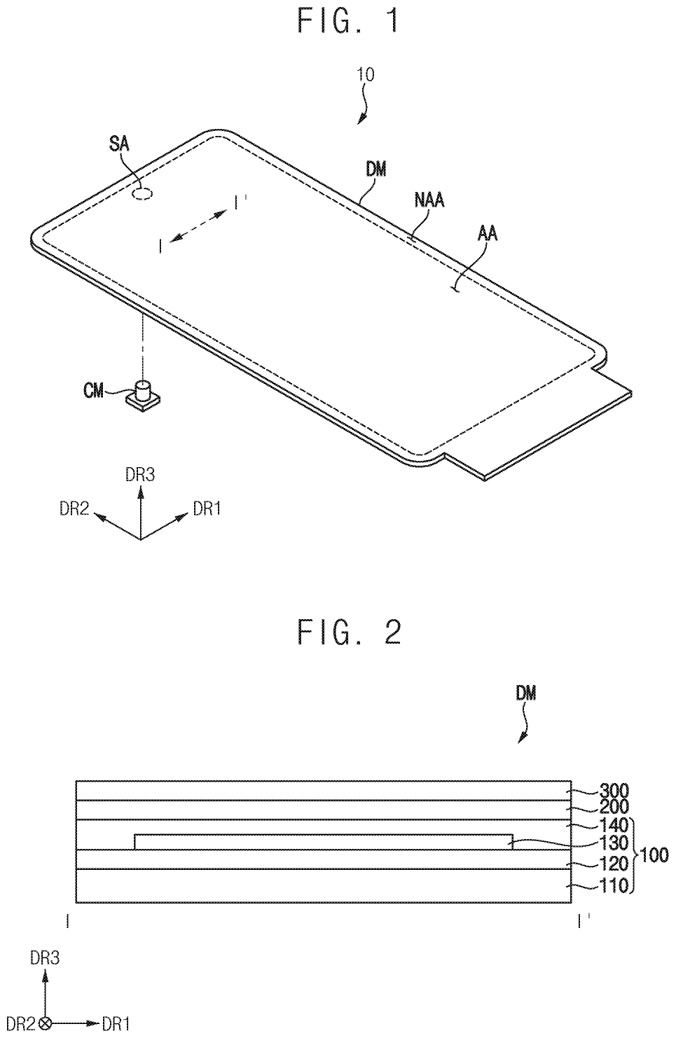

Unless otherwise defined or implied herein, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. FIG. 1 is a view illustrating a display device according to an embodiment.

Referring to FIG. 1, a display device 10 according to an embodiment may include a display module DM and an electronic module CM. The display module DM may generate an image and detect externally applied pressure. The electronic module CM may be disposed under or below the display module DM.

The display module DM may include an active area AA and a non-active area NAA. The display device 10 may display an image through the active area AA of the display module DM. The active area AA may include a plane defined by a first direction DR1 and a second direction DR2 perpendicular to the first direction DR1. For example, the display device 10 may display an image in a third direction DR3 perpendicular to the plane through the active area AA of the display module DM. The non-active area NAA may be positioned around the active area AA. For example, the non-active area NAA may surround the active area AA.

In an embodiment, the active area AA may include a first area A1 and a second area A2. For example, the first area A1 may be a portion of the active area AA. For example, the first area A1 may display an image and transmit an external input provided to the electronic module CM and/or an output provided from the electronic module CM. The first area A1 may have higher transmittance than other areas in the active area AA. Although FIG. 1 illustrates that one first area or a first area A1 is defined within the active area AA, the number of first areas A1 is not necessarily limited thereto. The second area A2 may be adjacent to the first area A1 and may surround the first area A1. Here, the first area A1 may correspond to a sensing area SA.

The electronic module CM may be disposed in an area overlapping the first area A1. As described above, the electronic module CM may receive an external input transmitted through the first area A1 or provide an output to the outside through the first area A1. For example, the electronic module CM may be a camera module, a sensor for measuring a distance, a sensor for recognizing a part of the user's body, a small lamp for outputting light, or the like within the spirit and the scope of the disclosure. However, the type of the electronic module CM is not necessarily limited thereto.

FIG. 2 is a schematic cross-sectional view illustrating a display module included in the display device of FIG. 1. For example, FIG. 2 is a schematic cross-sectional view taken along line I-I′ of FIG. 1.

Referring to FIGS. 1 and 2, the display module DM may include a display panel 100, a sensing layer 200, and an anti-reflection layer 300. The display panel 100 may include a substrate 110, a circuit element layer 120, a light emitting element layer 130, and an encapsulation layer 140.

The display panel 100 may substantially generate an image. For example, the display panel 100 may be an organic light emitting display panel, an inorganic light emitting display panel, a quantum dot display panel, or the like within the spirit and the scope of the disclosure. Hereinafter, a case in which the display panel 100 is an organic light emitting display panel will be limitedly described, but the configuration of the disclosure is not necessarily limited thereto.

The substrate 110 may be an insulating substrate made of a transparent or opaque material. The substrate 110 may have a single-layer or multi-layer structure. In an embodiment, the substrate 110 may include glass. The substrate 110 may be a rigid substrate. In an embodiment, the substrate 110 may include plastic. The substrate 110 may be a flexible substrate.

The circuit element layer 120 may be disposed on the substrate 110. The circuit element layer 120 may include an inorganic layer and a metal pattern. A pixel circuit may be implemented through the inorganic layer and the metal pattern.

The light emitting element layer 130 may be disposed on the circuit element layer 120. The light emitting element layer 130 may include light emitting diodes. For example, the light emitting element layer 130 may include organic light emitting materials, inorganic light emitting materials, organic-inorganic light emitting materials, quantum dots, and the like within the spirit and the scope of the disclosure. Hereinafter, the case in which the light emitting element layer 130 may include an organic light emitting material is limitedly described, but the configuration of the disclosure is not necessarily limited thereto.

The encapsulation layer 140 may be disposed on the light emitting element layer 130. The encapsulation layer 140 may include at least one inorganic encapsulation layer and at least one organic encapsulation layer. For example, the encapsulation layer 140 may include a first inorganic encapsulation layer disposed on the light emitting element layer 130, an organic encapsulation layer disposed on the first inorganic encapsulation layer, and a second inorganic encapsulation layer disposed on the organic encapsulation layer. The encapsulation layer 140 may prevent penetration of moisture, air, and the like into the light emitting element layer 130.

The sensing layer 200 may be disposed on the display panel 100. In other words, the sensing layer 200 may be disposed on the encapsulation layer 140. The sensing layer 200 may detect an external input applied from the outside. For example, the external input may be a user's touch. In an embodiment, the sensing layer 200 may be formed on the display panel 100 through a continuous process. An additional component (for example, an adhesive member) may not be disposed between the display panel 100 and the sensing layer 200. In an embodiment, the display panel 100 and the sensing layer 200 may be coupled or connected to each other through an adhesive member.

The anti-reflection layer 300 may be disposed on the sensing layer 200. The anti-reflection layer 300 may suppress reflection of external light incident from the outside of the display module DM. In an embodiment, the anti-reflection layer 300 may include a phase retarder and a polarizer. The phase retarder and the polarizer may be implemented as one polarizing film. In an embodiment, the anti-reflection layer 300 may include color filters. The color filters may have a given arrangement. For example, the color filters may be arranged or disposed in consideration of colors emitted by pixels included in the display panel 100. In an embodiment, the sensing layer 200 may be omitted. In case that the sensing layer 200 is omitted, the anti-reflection layer 300 may be disposed on the display panel 100. For example, the anti-reflection layer 300 may be formed on the display panel 100 through a continuous process. Positions of the sensing layer 200 and the antireflection layer 300 may be different from each other. For example, the anti-reflection layer 300 may be disposed between the display panel 100 and the sensing layer 200.

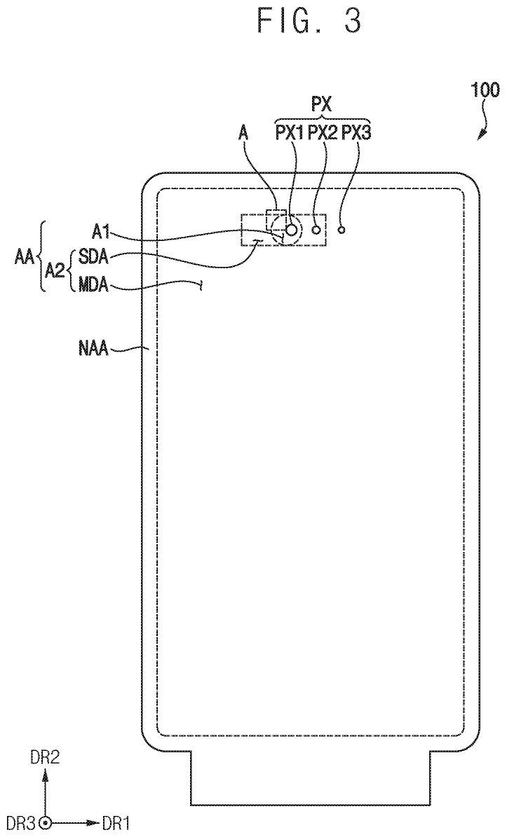

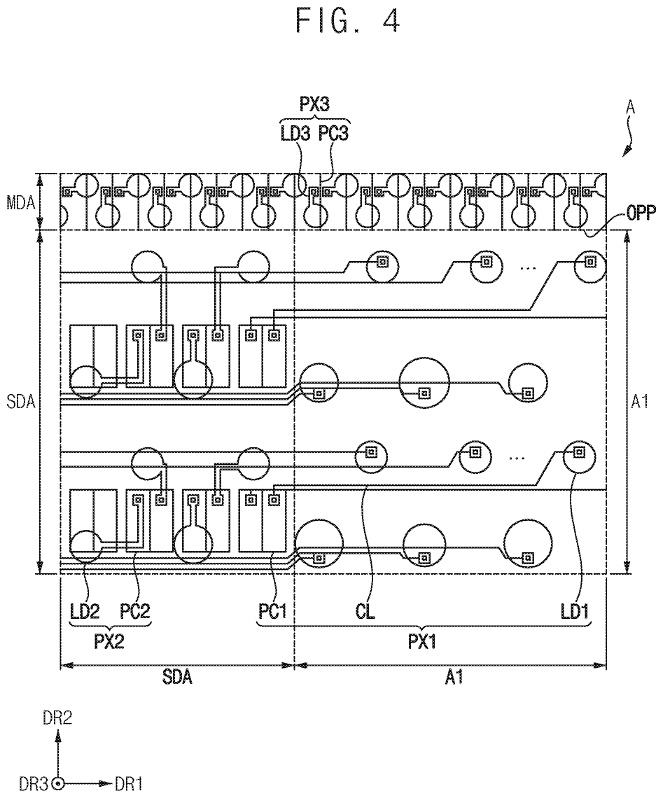

FIG. 3 is a schematic plan view illustrating a display panel included in the display module of FIG. 2. FIG. 4 is an enlarged view illustrating an enlarged area ‘A’ of FIG. 3.

Referring to FIGS. 3 and 4, as the display module DM may include the active area AA and the non-active area NAA, the display panel 100 MAY include the active area AA and the non-active area NAA.

The active area AA may include the first area A1 and the second area A2. The second area A2 may include an auxiliary display area SDA and a main display area MDA. The first area A1 may be referred to as a component area. The auxiliary display area SDA may be referred to as a middle area or a transition area. The main display area MDA may be referred to as a normal display area.

The first area A1 may be an area overlapping the electronic module CM of FIG. 1 in a plan view. For example, an external input may be provided to the electronic module CM through the first area A1, and an output from the electronic module CM may be emitted to the outside through the first area A1. Although the first area A1 is illustrated as having a circular shape in FIG. 3, the configuration of the disclosure is not necessarily limited thereto. For example, the first area A1 may have various shapes such as a polygonal shape, an ellipse shape, an atypical shape, or the like within the spirit and the scope of the disclosure.

The auxiliary display area SDA may be adjacent to the first area A1. For example, the auxiliary display area SDA may surround the first area A1. In an embodiment, the auxiliary display area SDA may have a lower transmittance than the first area A1. In an embodiment, the auxiliary display area SDA may be spaced apart from the non-active area NAA. However, it is not necessarily limited thereto, and in an embodiment, the auxiliary display area SDA may contact the non-active area NAA.

The main display area MDA may be adjacent to the auxiliary display area SDA. In an embodiment, the main display area MDA may have a lower transmittance than the first area A1.

The display panel 100 may include pixels PX. The pixels PX may be disposed in the active area AA. The pixels PX may include a first pixel PX1, a second pixel PX2, and a third pixel PX3. The first pixel PX1 may emit light in the first area A1, the second pixel PX2 may emit light in the auxiliary display area SDA, and the third pixel PX3 may emit light in the main display area MDA.

Each of the first pixel PX1, the second pixel PX2, and the third pixel PX3 may be provided in plurality. Each of the first, second, and third pixels PX1, PX2, and PX3 may include a red pixel, a green pixel, and a blue pixel. In an embodiment, each of the first, second, and third pixels PX1, PX2, and PX3 may further include a white pixel.

The first pixel PX1 may include a first light emitting diode LD1 and a first pixel circuit PC1. The first pixel circuit PC1 may control current delivered to the first light emitting diode LD1. The second pixel PX2 may include a second light emitting diode LD2 and a second pixel circuit PC2. The second pixel circuit PC2 may control current delivered to the second light emitting diode LD2. The third pixel PX3 may include a third light emitting diode LD3 and a third pixel circuit PC3. The third pixel circuit PC3 may control current delivered to the third light emitting diode LD3.

In an embodiment, the first light emitting diode LD1 may be disposed in the first area A1 and the first pixel circuit PC1 may be disposed in the auxiliary display area SDA. In an embodiment, the first light emitting diode LD1 may be disposed in the non-active area NAA. Since the first pixel circuit PC1 is not disposed in the first area A1, transmittance of the first area A1 may be improved.

The first light emitting diode LD1 and the first pixel circuit PC1 may be electrically connected through a connection line CL. The connection line CL may include a transparent conductive material. For example, the connection line CL may include a transparent conductive oxide (TCO) such as indium tin oxide (ITO), indium zinc oxide (IZO), indium gallium zinc oxide (IGZO), zinc oxide (ZnO), indium oxide (In2O3), and the like within the spirit and the scope of the disclosure.

By way of example, the first light emitting diode LD1 may be disposed in the first area A1, and the first pixel circuit PC1, the second light emitting diode LD2, and the second pixel circuit PC2 may be disposed in the auxiliary display area SDA, and the third light emitting diode LD3 and the third pixel circuit PC3 may be disposed in the main display area MDA.

Accordingly, the transmittance of the auxiliary display area SDA and the transmittance of the main display area MDA may be lower than the transmittance of the first area A1. As the first pixel circuit PC1 is disposed in the auxiliary display area SDA, the number of second pixels PX2 disposed in the auxiliary display area SDA may be smaller than the number of third pixels PX3 disposed in the main display area MDA within a unit area.

In an embodiment, each of the first light emitting diode LD1, the second light emitting diode LD2, and the third light emitting diode LD3 may be provided in plurality. A distance between the two most adjacent first light emitting diodes among the first light emitting diodes LD1 may be larger than the distance between the two most adjacent third light emitting diodes among the third light emitting diodes LD3.

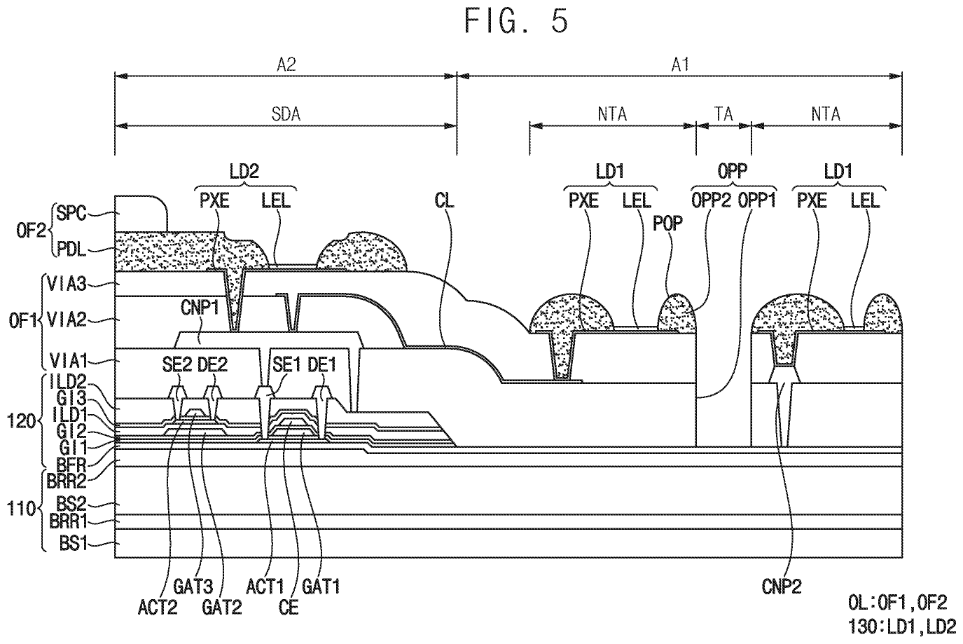

FIG. 5 is a schematic cross-sectional view illustrating a portion of each of an auxiliary display areas included in a first area and a second area of the display panel of FIG. 3.

Referring further to FIG. 5, the first area A1 may include a transmission area TA and a non-transmission area NTA. The non-transmission area NTA may be adjacent to the transmission area TA. The transmission area TA may surround the non-transmission area NTA.

The transmission area TA may be an area through which external light incident on the display device 10 is transmitted. Since the first area A1 may include the transmission area TA through which external light passes, the electronic module CM overlapping the first area A1 may detect or recognize an object or user positioned in front of the display device 10 through the transmission area TA. The non-transmission area NTA may be an area from which light generated from the display panel 100 is emitted.

The substrate 110 may include a first base substrate BS1, a first barrier layer BRR1, a second base substrate BS2, and a second barrier layer BRR2.

By way of example, the first barrier layer BRR1 may be disposed on the first base substrate BS1. The second base substrate BS2 may be disposed on the first barrier layer BRR1. The second barrier layer BRR2 may be disposed on the second base substrate BS2. The first base substrate BS1, the first barrier layer BRR1, and the second base substrate BS2 may prevent permeation of external moisture. The first base substrate BS1 and the second base substrate BS2 may be formed of a double layer in order to delay water permeation time.

The circuit element layer 120 may be disposed on the substrate 110. The circuit element layer 120 may be disposed in the auxiliary display area SDA included in the second area A2. For example, the circuit element layer 120 may not be disposed in the first area A1.

The circuit element layer 120 may include a buffer layer BFR, insulating layers, a first active layer ACT1, a first gate layer, a second gate layer, a second active layer ACT2, a third gate layer, and a first conductive layer.

The buffer layer BFR may be disposed on the second barrier layer BRR2. The buffer layer BFR may prevent diffusion of metal atoms or impurities from the substrate 110. The buffer layer BFR may extend from the second area A2 to the first area A1.

In the auxiliary display area SDA, the first active layer ACT1 may be disposed on the buffer layer BFR. The first active layer ACT1 may be divided into a source region and a drain region doped with impurities and a channel region between the source region and the drain region. For example, the first active layer ACT1 may include a silicon semiconductor.

In the auxiliary display area SDA, a first gate insulating layer GI1 may cover the first active layer ACT1 and may be disposed on the buffer layer BFR. The first gate insulating layer GI1 may include an inorganic material. For example, the first gate insulating layer GI1 may include silicon oxide. The first gate insulating layer GI1 may overlap the second area A2 and may not overlap the first area A1.

In the auxiliary display area SDA, the first gate layer may be disposed on the first gate insulating layer GI1. The first gate layer may include a first gate electrode GAT1. The first gate electrode GAT1 may overlap the channel region of the first active layer ACT1.

In the auxiliary display area SDA, a second gate insulating layer GI2 may cover the first gate layer and may be disposed on the first gate insulating layer GI1. The second gate insulating layer GI2 may include an inorganic material. For example, the second gate insulating layer GI2 may include silicon nitride. The second gate insulating layer GI2 may overlap the second area A2 and may not overlap the first area A1.

In the auxiliary display area SDA, the second gate layer may be disposed on the second gate insulating layer GI2. The second gate layer may include a capacitor electrode CE and a second gate electrode GAT2. The capacitor electrode CE may overlap the first gate electrode GAT1. The capacitor electrode CE and the first gate electrode GAT1 may constitute a first storage capacitor. The second gate electrode GAT2 may be spaced apart from the capacitor electrode CE.

In the auxiliary display area SDA, the second active layer ACT2 may be disposed on the first interlayer insulating layer ILD1. The second active layer ACT2 may be divided into a source region, a drain region and a channel region between the source region and the drain region. The source region and the drain region may be doped with impurities or by hydrogen diffusion between processes. For example, the second active layer ACT2 may include an oxide semiconductor. For example, the second active layer ACT2 may include a material different from a material of the first active layer ACT1. However, the disclosure is not limited thereto, and the second active layer ACT2 may include the same material or a similar material as the first active layer ACT1.

In the auxiliary display area SDA, a third gate insulating layer GI3 may cover the second active layer ACT2 and may be disposed on the first interlayer insulating layer ILD1. The third gate insulating layer GI3 may include an inorganic material. For example, the third gate insulating layer GI3 may include silicon oxide. The third gate insulating layer GI3 may overlap the second area A2 and may not overlap the first area A1.

In the auxiliary display area SDA, the third gate layer may be disposed on the third gate insulating layer GI3. The third gate layer may include a third gate electrode GAT3. The third gate electrode GAT3 may overlap the channel region of the second active layer ACT2. The third gate electrode GAT3 may overlap the second gate electrode GAT2. The third gate electrode GAT3 and the second gate electrode GAT2 may constitute a second storage capacitor. However, the disclosure is not limited thereto.

In the auxiliary display area SDA, the second interlayer insulating layer ILD2 may cover the third gate layer and may be disposed on the third gate insulating layer GI3. The second interlayer insulating layer ILD2 may overlap the second area A2 and may not overlap the first area A1.

The first conductive layer may be disposed on the second interlayer insulating layer ILD2. The first conductive layer may include a first source electrode SE1, a first drain electrode DE1, a second source electrode SE2, and a second drain electrode DE2. The first source electrode SE1 and the first drain electrode DE1 may be connected to the first active layer ACT1. The second source electrode SE2 and the second drain electrode DE2 may be connected to the second active layer ACT2.

For example, the first active layer ACT1, the first gate electrode GAT1, the first source electrode SE1, and the first drain electrode DE1 may constitute a first pixel circuit PC1. The second active layer ACT2, the third gate electrode GAT3, the second source electrode SE2, and the second drain electrode DE2 may constitute a second pixel circuit PC2. However, the disclosure is not limited thereto.

A first via insulating layer VIA1 may cover the first conductive layer and may be disposed on the second interlayer insulation layer ILD2. The first via insulating layer VIA1 may include an organic material. For example, the first via insulation layer VIA1 may include polyimide. The first via insulating layer VIA1 may planarize an upper surface of a stacked structure. The first via insulating layer VIA1 may extend from the second area A2 to the first area A1.

The second conductive layer may be connected to the circuit element layer 120 on the circuit element layer 120. The second conductive layer may be disposed on the first via insulating layer VIA1. The second conductive layer may include a first connection electrode CNP1 and a second connection electrode CNP2, collectively CNP. The first connection electrode CNP1 may contact the first drain electrode DE1 or the first source electrode SE1 in the second area A2. The first connection electrode CNP1 may connect the light emitting diode LD and the circuit element layer 120. The second connection electrode CNP2 may be disposed in the first area A1.

A second via insulating layer VIA2 may be disposed on the first via insulating layer VIA1. The second via insulating layer VIA2 may cover the first connection electrode CNP1. The second via insulating layer VIA2 may include an organic material. For example, the second via insulating layer VIA2 may include polyimide. The second via insulating layer VIA2 may planarize an upper surface of the stacked structure. The second via insulating layer VIA2 may overlap the second area A2 and may not overlap the first area A1.

A third via insulating layer VIA3 may be disposed on the second via insulating layer VIA2. The third via insulating layer VIA3 may cover the connection line CL. The third via insulating layer VIA3 may include an organic material. For example, the third via insulating layer VIA3 may include polyimide. The third via insulating layer VIA3 may planarize an upper surface of the stacked structure. The third via insulating layer VIA3 may extend from the second area A2 to the first area A1.

The light emitting element layer 130 may be disposed on the circuit device layer 120. The light emitting element layer 130 may be disposed on the third via insulating layer VIA3. The light emitting element layer 130 may include at least one light emitting diode.

For example, the light emitting element layer 130 may include the first light emitting diodes LD1 and the second light emitting diodes LD2. The first light emitting diodes LD1 may be disposed in the non-transmission area NTA and may be connected to the circuit element layer (for example, the first pixel circuit PC1 of FIG. 4). The second light emitting diodes LD2 may be disposed in the second area A2 and may be connected to the circuit element layer (for example, the second pixel circuit PC2 of FIG. 4).

By way of example, each of the first light emitting diodes LD1 may be connected to the circuit element layer 120 through the connection line CL. The connection line CL may be connected to the first connection electrode CNP1. The connection line CL may be disposed on the first via insulating layer VIA1 and the second via insulating layer VIA2. However, the disclosure is not limited thereto.

The connection line CL disposed on the first via insulating layer VIA1 and the second via insulating layer VIA2 may be directly connected to the first light emitting diode LD1. The second light emitting diodes LD2 may be connected to the circuit element layer 120 through the first connection electrode CNP1.

Each of the first light emitting diodes LD1 and the second light emitting diodes LD2 may include a pixel electrode PXE, a light emitting layer LEL, and a common electrode.

The pixel electrode PXE may be disposed on the third via insulating layer VIA3. The pixel electrode PXE may contact the first connection electrode CNP1 or the second connection electrode CNP2. The pixel electrode PXE included in the second light emitting diode LD2 may be connected to the circuit element layer 120 through the first connection electrode CNP1. The pixel electrode PXE included in the first light emitting diode LD1 may be connected to the circuit element layer 120 through the connection line CL and the second connection electrode CNP2.

The pixel defining layer PDL may be disposed on the third via insulating layer VIA3. The pixel defining layer PDL may include a pixel opening POP exposing a portion of the pixel electrode PXE. The pixel defining layer PDL may include an organic material or an inorganic material. For example, the pixel defining layer PDL may include polyimide. The pixel defining layer PDL may further include a black pigment or black dye.

The spacer SPC may be disposed on the pixel defining layer PDL. The spacer SPC may include an organic material or an inorganic material. The spacer SPC may maintain a gap between the encapsulation layer 140 and the substrate 110.

The spacer SPC may include an organic material or an inorganic material. The spacer SPC may include the same material or a similar material as the pixel defining layer PDL. For example, the pixel defining layer PDL and the spacer SPC may include an organic material such as polyimide. However, the disclosure is not limited thereto.

The light emitting layer LEL may be disposed on the pixel electrode PXE. The light emitting layer LEL may be disposed within the pixel opening POP included in the pixel defining layer PDL. In an embodiment, the light emitting layer LEL may have a multilayer structure including a hole injection layer, a hole transport layer, an organic light emitting layer, an electron transport layer, and an electron injection layer. The organic light emitting layer may include a light emitting material.

The common electrode may cover the light emitting layer LEL and may be disposed on the pixel defining layer PDL and the spacer SPC. In an embodiment, the common electrode may have a plate shape. The common electrode may have a light transmitting property or a reflective property. For example, the common electrode may include metal.

The encapsulation layer 140 may be disposed on the common electrode and may cover the light emitting element layer 130.

In an embodiment, the first, second, and third via insulating layers VIA1, VIA2, and VIA3 may form a first organic film OF1. Accordingly, the first organic film OF1 may be disposed between the circuit element layer 120 and the light emitting element layer 130 and may overlap the first light emitting diodes LD1. For example, the first organic film OF1 may be disposed under or below the pixel electrode PXE and may overlap the pixel electrode PXE.

The pixel defining layer PDL and the spacer SPC may constitute a second organic film OF2. Accordingly, the second organic film OF2 may be disposed on the first organic film OF1 and may be adjacent to the first light emitting diodes LD1. The second organic film OF2 may include the pixel opening POP exposing a portion of the pixel electrode PXE on the pixel electrode PXE.

The first organic film OF1 may overlap the second area A2 and the non-transmission area NTA of the first area A1. The second organic film OF2 may overlap the second area A2 and the non-transmission area NTA of the first area A1. For example, the second organic film OF2 may overlap the first organic film OF1.

The first organic film OF1 may include a first opening OPP1 overlapping the transmission area TA. The first opening OPP1 may expose the buffer layer BFR disposed in the first area A1. The second organic film OF2 may include a second opening OPP2 overlapping the transmission area TA. The second opening OPP2 may overlap the first opening OPP1.

The first organic film OF1 and the second organic film OF2 may constitute an organic layer OL. For example, the organic layer OL may include the first organic film OF1 and the second organic film OF2. Accordingly, the organic layer OL may be disposed on the circuit element layer 120 and may be adjacent to the light emitting element layer 130.

The first opening OPP1 and the second opening OPP2 may constitute an opening OPP. Accordingly, the organic layer OL may include the opening OPP overlapping the transmission area TA. The opening OPP may expose the buffer layer BFR. The opening OPP may be defined between the first light emitting diodes LD1 in the first area A1. For example, the opening OPP may be spaced apart from the first light emitting diodes LD1 in a plan view.

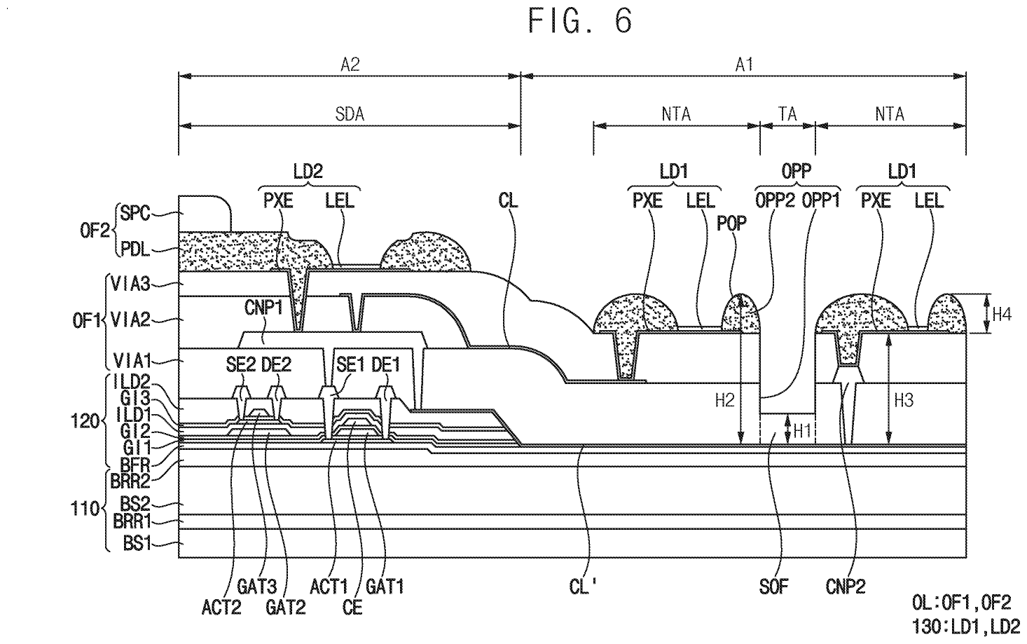

FIG. 6 is a schematic cross-sectional view illustrating another portion of each of an auxiliary display areas included in a first area and a second area of the display panel of FIG. 3.

Further referring to FIG. 6, the display panel 100 may further include a connection line CL′ on the second interlayer insulating layer ILD2.

The connection line CL′ may be disposed on the second interlayer insulating layer ILD2 in the second area A2 and may be disposed on the buffer layer BFR in the first area A1.

The connection line CL′ disposed on the second interlayer insulating layer ILD2 may be connected to the circuit element layer 120 through the first connection electrode CNP1. The connection line CL′ may be connected to the first light emitting diode LD1 through the second connection electrode CNP2. For example, the connection line CL′ may connect the circuit element layer 120 and the first light emitting diode LD1.

In an embodiment, the display panel 100 may further include a sub-organic film SOF. The sub-organic film SOF may cover the connection line CL′ in the transmission area TA.

The organic layer OL may include the opening OPP overlapping the transmission area TA. However, even in the transmission area TA, the sub-organic film SOF may be additionally disposed in an area where the connection line CL′ is positioned. For example, the sub-organic film SOF may be an organic layer overlapping the connection line CL′ in the opening OPP.

In an embodiment, a height H1 of the sub organic layer SOF may be smaller than a sum of a height H3 of the first organic film OF1 and a height H4 of the second organic film OF2. In an embodiment, there may also be included a second height H2.

In an embodiment, the sub-organic film SOF may extend from the first organic film OF1 to the transmission area TA. However, the disclosure is not limited thereto, and the first organic film OF1 and the sub-organic film SOF may be spaced apart from each other due to a level difference. For example, the sub-organic film SOF may include the same material or a similar material as the first organic film OF1. The height H1 of the sub organic layer SOF may be smaller than the height H3 of the first organic film OF1.

For example, the sub-organic film SOF may be a portion extending from one of the first, second, and third via insulating layers VIA1, VIA2, and VIA3. For example, in case that the sub organic film SOF extends from the first via insulating layer VIA1, the height H1 of the sub organic film SOF may be smaller than a height of the first via insulating layer VIA1. For another example, in case that the portion extends from the third via insulating layer VIA3 that is the sub-organic film SOF, the height H1 of the sub organic layer SOF may be smaller than a height of the third via insulating layer VIA3.

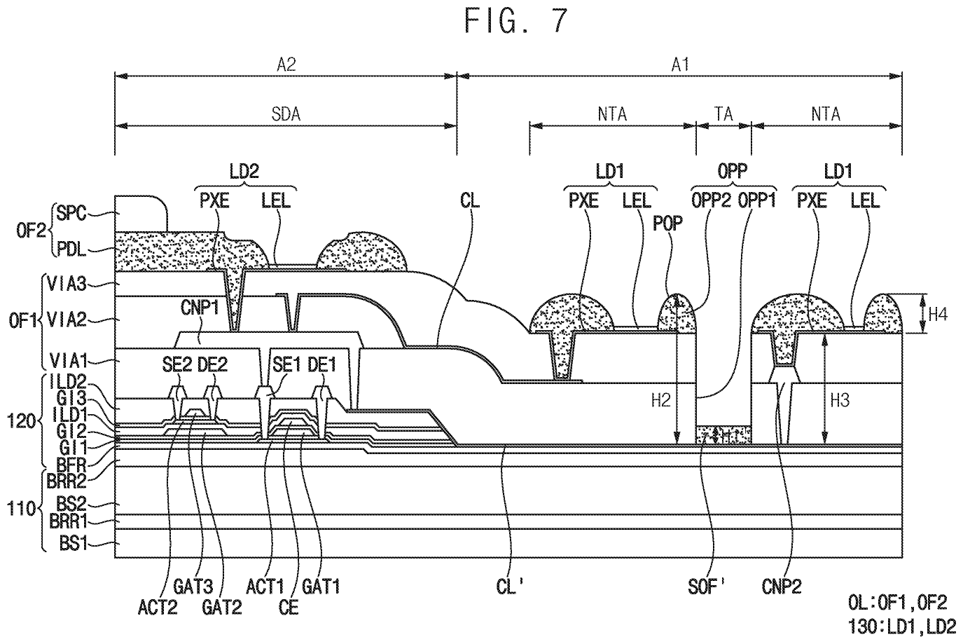

FIG. 7 is a schematic cross-sectional view illustrating another example of FIG. 6.

Referring to FIG. 7, in an embodiment, the display panel 100 may further include a sub-organic film SOF′. The sub-organic film SOF′ may cover the connection line CL′ in the transmission area TA.

The organic layer OL may include the opening OPP overlapping the transmission area TA. However, even in the transmission area TA, the sub-organic film SOF′ may be additionally disposed in an area where the connection line CL′ is positioned. For example, the sub-organic film SOF′ may be an organic layer overlapping the connection line CL′ in the opening OPP.

In an embodiment, the sub-organic film SOF′ may extend from the second organic film OF2 to the transmission area TA. However, the disclosure is not limited thereto, and the second organic film OF2 and the sub-organic film SOF′ may be spaced apart from each other due to a level difference. For example, the sub-organic film SOF′ may include the same material or a similar material as the second organic film OF2. A height H1 of the sub-organic film SOF′ may be smaller than a height H3 of the second organic film OF2.

The sub-organic film SOF′ may be a portion extending from one of the pixel defining layer PDL and the spacer SPC. For example, in case that the sub-organic film SOF′ extends from the pixel defining layer PDL, the height H1 of the sub-organic film SOF′ may be smaller than the height H4 of the pixel defining layer PDL. In case that the pixel defining layer PDL further may include a black dye or black pigment, the sub-organic film SOF′ may further include a black dye or black pigment.

For another example, in case that the sub-organic film SOF′ extends from the spacer SPC, the height H1 of the sub-organic film SOF′ may be smaller than the height of the spacer SPC.

In an embodiment, since the display device 10 may include the organic layer OL including the opening OPP overlapping the transmission area TA, the transmittance in the first area A1 of the display device 10 may be improved. For example, since the organic layer OL is not disposed in the transmission area TA, reflection and absorption of light due to the organic layer OL may be minimized. Accordingly, display quality of the display device 10 may be improved.

Unnecessary light emission due to the connection line CL′ may be prevented by further disposing the sub-organic films SOF and SOF′ on the connection line CL′ disposed in the transmission area TA. Accordingly, display quality of the display device 10 may be improved.

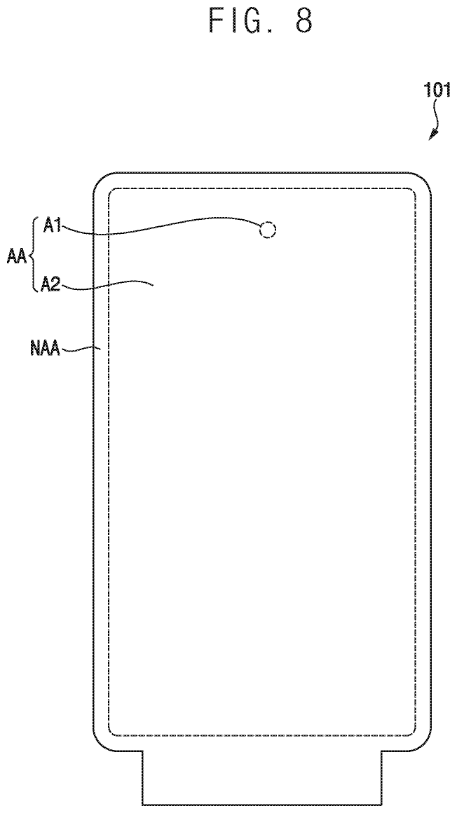

FIG. 8 is a schematic plan view illustrating another example of a display panel included in the display device of FIG. 1.

Referring to FIG. 8, the display device 10 may include a display panel 101.

The display panel 101 may include the active area AA and the non-active area NAA.

The active area AA may include the first area A1 and the second area A2. The first area A1 may be an area overlapping the electronic module CM of FIG. 1 in the plan view.

The second area A2 may be adjacent to the first area A1. For example, the second area A2 may surround the first area A1. In an embodiment, the second area A2 may have a lower transmittance than the first area A1.

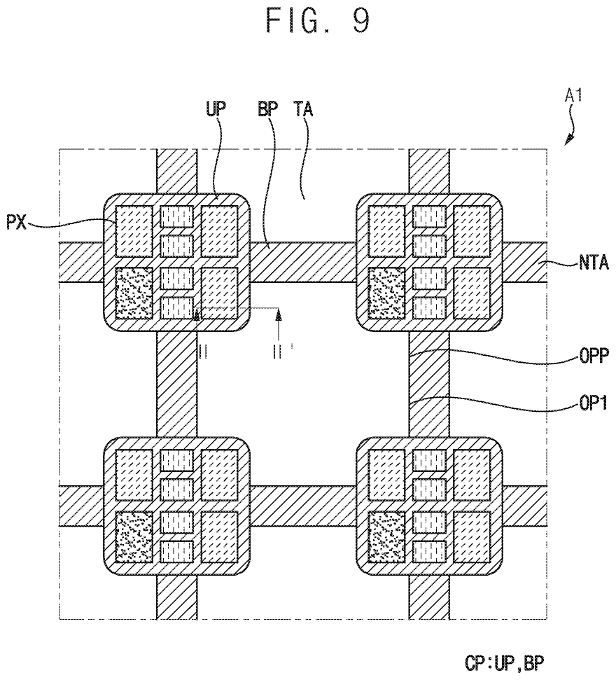

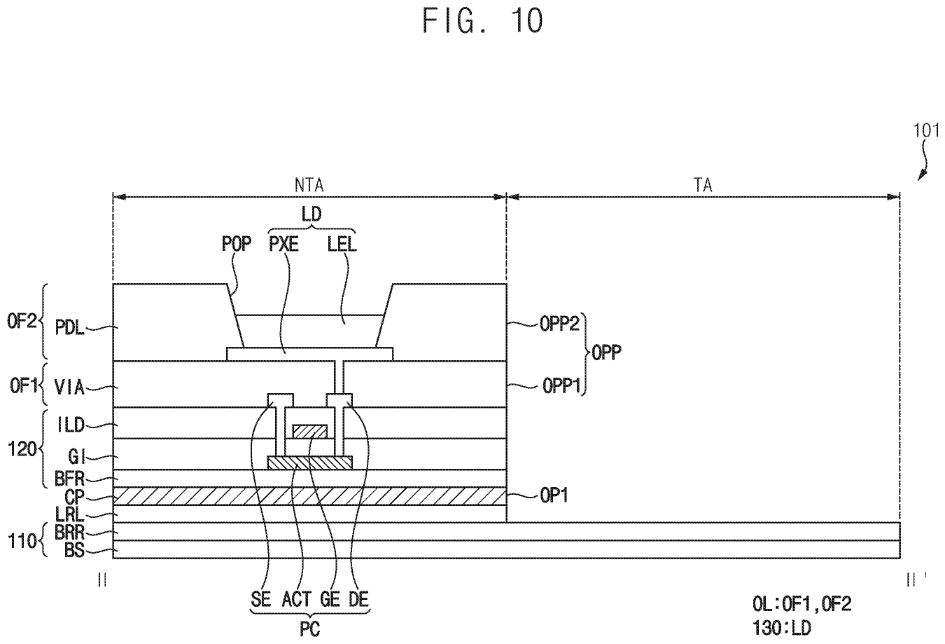

FIG. 9 is a schematic plan view illustrating an example of a first area included in the display panel of FIG. 8.

Referring further to FIG. 9, the display panel 101 may include a substrate 110, a conductive layer CP, and pixels PX. As the display panel 101 may include the first area A1 and the second area A2, the substrate 110 may include the first area A1 and the second area A2. The pixels PX may be disposed in the active area AA.

The first area A1 may include a transmission area TA and a non-transmission area NTA. The non-transmission area NTA may be adjacent to the transmission area TA. By way of example, the pixels PX may be disposed in the second area A2 and the non-transmission area NTA of the first area A1.

The display panel 101 may include the pixels PX. The pixels may include sub-pixels that emits light of different colors. For example, the sub-pixels may include a red sub-pixel that emits red light, a green sub-pixel that emits green light, and a blue sub-pixel that emits blue light.

The conductive layer CP may be disposed on the substrate 110 corresponding to the non-transmission area NTA. The conductive layer CP may overlap the non-transmission area NTA and may not overlap the transmission area TA.

For example, the transmission area TA may be an area in which the conductive layer CP and the pixels PX are not disposed, and the non-transmission area NTA may be an area in which the conductive layer CP and the pixels PX are disposed. Accordingly, the transmission area TA and the non-transmission area NTA may have a different arrangement depending on the shape of the conductive layer CP.

Since the first area A1 may include the transmission area TA, the number of sub-pixels per unit area of the first area A1 may be smaller than the number of sub-pixels per unit area of the second area A2. In other words, the resolution of the first area A1 may be smaller than that of the second area A2.

The conductive layer CP may include unit patterns UP and bridge patterns BP connecting the unit patterns UP. The unit patterns UP may be arranged or disposed in various ways. For example, the unit patterns UP may be arranged or disposed in a matrix form.

The conductive layer CP may include first openings OP1. For example, the first openings OP1 may be defined by the unit patterns UP and the bridge patterns BP. The first openings OP1 may overlap the transmission area TA.

By forming the first openings OP1 in the conductive layer CP, the transmission area TA may be defined. For example, external light may pass through the transmission area TA due to the first openings OP1.

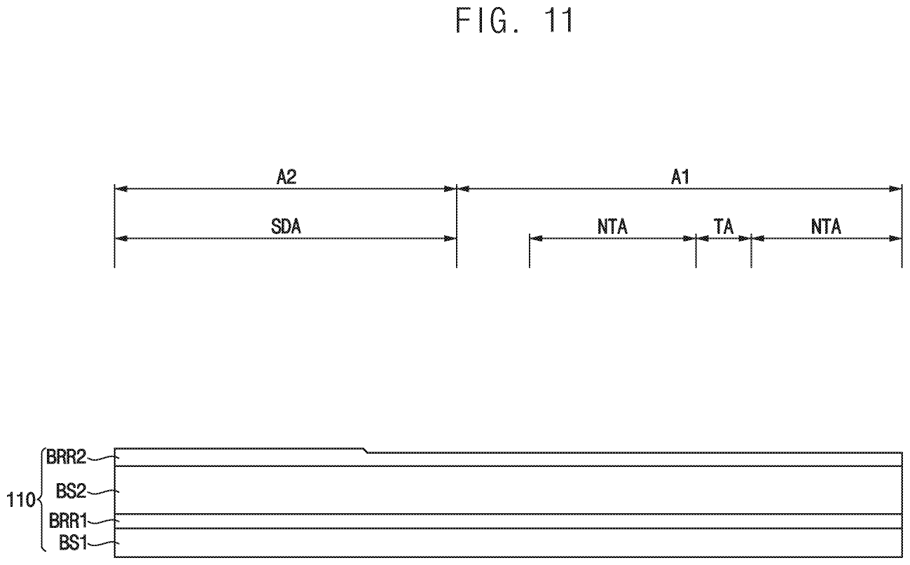

FIG. 10 is a schematic cross-sectional view taken along line II-II′ of FIG. 9.

FIGS. 8, 9, and 10, the display panel 101 may include the substrate 110, the barrier layer BRR, the low reflection layer LRL, the conductive layer CP, a circuit element layer 120, an organic layer OL, and a light emitting element layer 130.

The substrate 110 may include a base substrate 110 and a barrier layer BRR. The circuit element layer 120 may include a buffer layer BFR, a gate insulating layer GI, an interlayer insulating layer ILD, and a pixel circuit PC. The light emitting element layer 130 may include light emitting diodes LD. The circuit element layer 120 may be disposed in the non-transmission area NTA on the substrate 110. The light emitting element layer 130 may be disposed on the circuit device layer 120 and may be disposed in the non-transmission area NTA. The light emitting element layer 130 may be connected to the circuit element layer 120.

The pixel circuit PC may include an active layer ACT, a source electrode SE, a gate electrode GE, and a drain electrode DE. The light emitting diode LD may include a pixel electrode PXE, a light emitting layer LEL, and a common electrode.

The base substrate BS may include a transparent material or an opaque material. The barrier layer BRR may be disposed on the base substrate BS. The barrier layer BRR may prevent foreign substances from penetrating a lower portion of the base substrate BS.

In the non-transmission area NTA, the low reflection layer LRL may be disposed on the barrier layer BRR. In an embodiment, the low reflection layer LRL may include amorphous silicon, silicon, or a mixture thereof. The low reflection layer LRL may prevent external light from reaching the conductive layer CP.

In the non-transmission area NTA, the conductive layer CP may be disposed on the low reflection layer LRL. The conductive layer CP may block external light incident from the outside of the display device 10. For example, the conductive layer CP may include a metal material having low light transmittance.

In the non-transmission area NTA, the buffer layer BFR may be disposed on the conductive layer CP. The buffer layer BFR may cover the conductive layer CP. The buffer layer BFR may prevent penetration of foreign substances from the conductive layer CP. Examples of the material constituting the buffer layer BFR include silicon oxide, silicon nitride, silicon oxynitride, and the like within the spirit and the scope of the disclosure. These materials may be used alone or in combination.

In the non-transmission area NTA, the active layer ACT may be disposed on the buffer layer BFR. The active layer ACT may include a semiconductor material. For example, the active layer ACT may include a silicon-based semiconductor material. For another example, the active layer ACT may include an oxide-based semiconductor material.

In the non-transmission area NTA, the gate insulating layer GI may be disposed on the buffer layer BFR. The gate insulating layer GI may cover the active layer ACT. The gate insulating layer GI may insulate the active layer ACT from the gate electrode GE. The gate insulating layer GI may include an inorganic insulating material.

In the non-transmission area NTA, the gate electrode GE may be disposed on the gate insulating layer GI. The gate electrode GE may be disposed to overlap the active layer ACT. The gate electrode GE may include a conductive material. In case that an electrical signal is applied to the gate electrode GE, the source electrode SE and the drain electrode DE may be electrically connected.

In the non-transmission area NTA, the interlayer insulating layer ILD may be disposed on the gate insulating layer GI. The interlayer insulating layer ILD may cover the gate electrode GE. The interlayer insulating layer ILD may insulate the gate electrode GE and the source electrode SE. The interlayer insulating layer ILD may insulate the gate electrode GE and the drain electrode DE. The interlayer insulating layer ILD may include an inorganic insulating material.

In the non-transmission area NTA, the source electrode SE and the drain electrode DE may be disposed on the interlayer insulating layer ILD. The source electrode SE and the drain electrode DE may contact the active layer ACT. For example, the source electrode SE may contact one side or a side of the active layer ACT through a through hole passing through the interlayer insulating layer ILD and the gate insulating layer GI. Each of the source electrode SE and the drain electrode DE may include a conductive material.

In the non-transmission area NTA, the via insulating layer VIA may be disposed on the interlayer insulation layer ILD. The via insulating layer VIA may cover the source electrode SE and the drain electrode DE. The via insulating layer VIA may constitute a first organic film OF1.

In an embodiment, the first organic film OF1 may overlap the second area A2 and the non-transmission area NTA, and may overlap the light emitting diodes LD. For example, the first organic film OF1 may include a first opening OPP1 overlapping the transmission area TA.

Although the via insulating layer VIA is shown as a single layer in the FIG. 10, it is not limited thereto, and the via insulating layer VIA may have multiple layers.]

In the non-transmission area NTA, the pixel electrode PXE may be disposed on the via insulating layer VIA. The pixel electrode PXE may be connected to the drain electrode DE. For example, the pixel electrode PXE may contact one side or a side of the drain electrode DE through a through hole penetrating the via insulation layer VIA. The pixel electrode PXE may include a conductive material.

In the non-transmission area NTA, the pixel defining layer PDL may be disposed on the via insulating layer VIA. The pixel defining layer PDL may cover at least a portion of the pixel electrode PXE. The pixel defining layer PDL may include a pixel opening POP exposing at least a portion of the pixel electrode PXE.

In an embodiment, in the non-transmission area NTA, the pixel defining layer PDL may constitute a second organic film OF2. The second organic film OF2 may be disposed on the first organic film OF1. The second organic film OF2 may overlap the second area A2 and the non-transmission area NTA, and may be adjacent to the light emitting diodes LD. For example, the second organic film OF2 may include a second opening OPP2 overlapping the pixel opening POP and the transmission area TA.

In an embodiment, in the non-transmission area NTA, the first organic film OF1 and the second organic film OF2 may constitute the organic layer OL. Accordingly, the organic layer OL may be disposed on the circuit element layer 120 and may be adjacent to the light emitting element layer 130. The organic layer OL may include an opening OPP overlapping the transmission area TA. The opening OPP may be defined between the light emitting diodes LD and may be spaced apart from the light emitting diodes LD in the plan view. The opening OPP may overlap the first opening OP1.

In the non-transmission area NTA, the light emitting layer LEL may be disposed on the pixel electrode PXE. The light emitting layer LEL may be disposed in the pixel opening POP.

In the non-transmission area NTA, the common electrode may be disposed on the pixel defining layer PDL. The common electrode may be disposed while covering the light emitting layer LEL.

In an embodiment, since the display device 10 may include the organic layer OL including the opening OPP overlapping the transmission area TA, the transmittance in the first area A1 of the display device 10 may be improved. For example, since the organic layer OL is not disposed in the transmission area TA, reflection and absorption of light due to the organic layer OL may be minimized. Accordingly, display quality of the display device 10 may be improved.

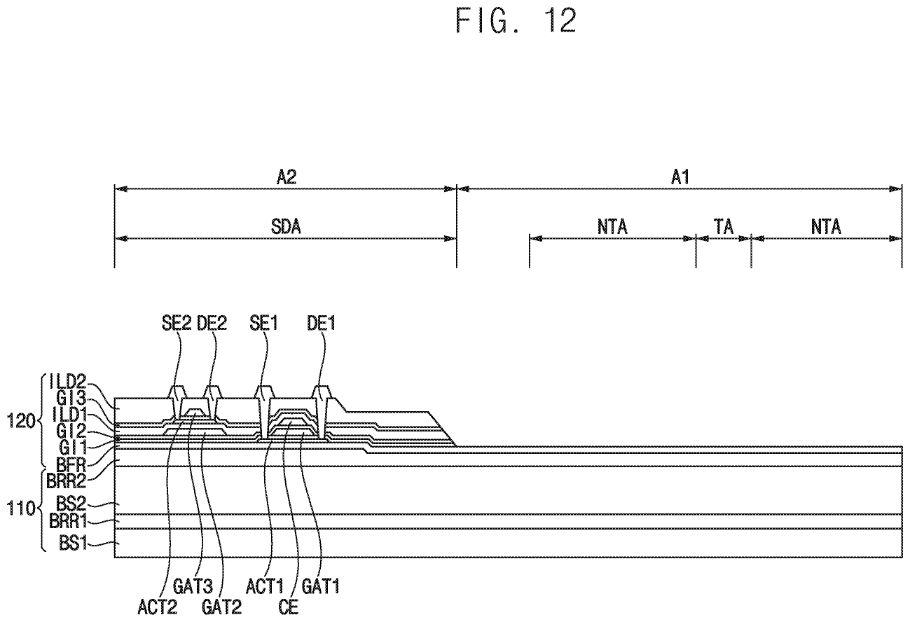

FIGS. 11, 12, 13, 14, 15, 16, 17, 18, 19, 20, and 21 are views illustrating a method of manufacturing a display device according to an embodiment.

The method of manufacturing the display device described with reference to FIGS. 11, 12, 13, 14, 15, 16, 17, 18, 19, 20, and 21 may be the method of manufacturing the display device 10 of FIGS. 1, 2, 3, 4, and 5.

Referring to FIG. 11, a substrate 110 including a first area A1 and a second area A2 adjacent to the first area A1 may be formed. The first area A1 may include a transmission area TA and a non-transmission area NTA.

By way of example, a first base substrate BS1 may be formed. A first barrier layer BRR1 may be formed on the first base substrate BS1. A second base substrate BS2 may be formed on the first barrier layer BRR1. A second barrier layer BRR2 may be formed on the second base substrate BS2.

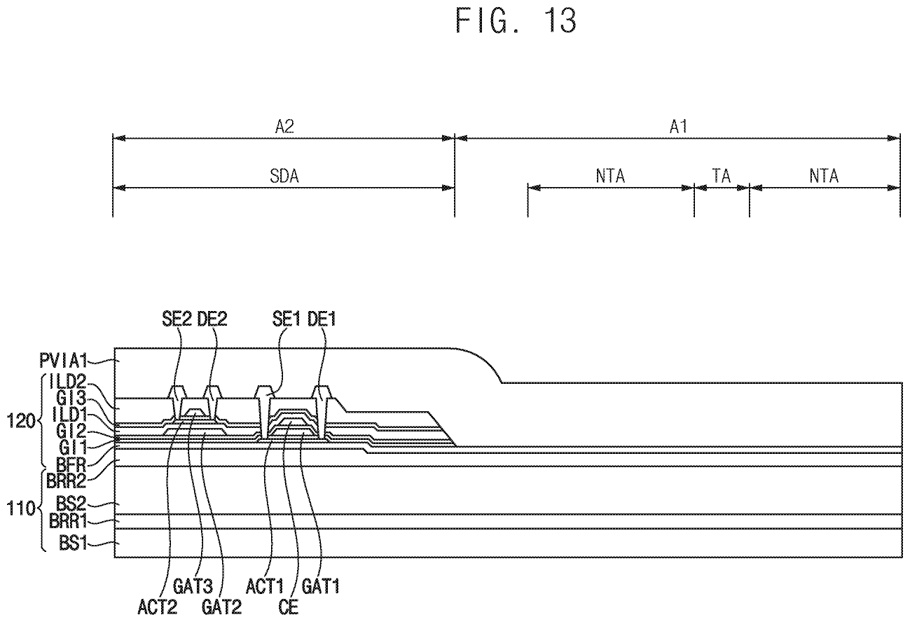

Referring further to FIG. 12, a circuit element layer 120 may be formed on the substrate 110.

By way of example, a buffer layer BFR may be formed on the second barrier layer BRR2 in the first area A1 and the second area A2. In the auxiliary display area SDA, a first active layer ACT1 may be formed on the buffer layer BFR. A first gate insulating layer GI1 may be formed on the buffer layer BFR to cover the first active layer ACT1. A first gate electrode GAT1 may be formed on the first gate insulating layer GI1. A second gate insulating layer GI2 may be formed on the first gate insulating layer GI1 to cover the first gate electrode GAT1. A second gate electrode GAT2 and a capacitor electrode CE may be formed on the second gate insulating layer GI2. A first interlayer insulating layer ILD1 may be formed on the second gate insulating layer GI2 to cover the second gate electrode GAT2 and the capacitor electrode CE. A second active layer ACT2 may be formed on the first interlayer insulating layer ILD1. A third gate insulating layer GI3 may be formed on the first interlayer insulating layer ILD1 to cover the second active layer ACT2. A first source electrode SE1, a first drain electrode DE1, a second source electrode SE2, and a second drain electrode DE2 may be formed on the third gate insulating layer GI3.

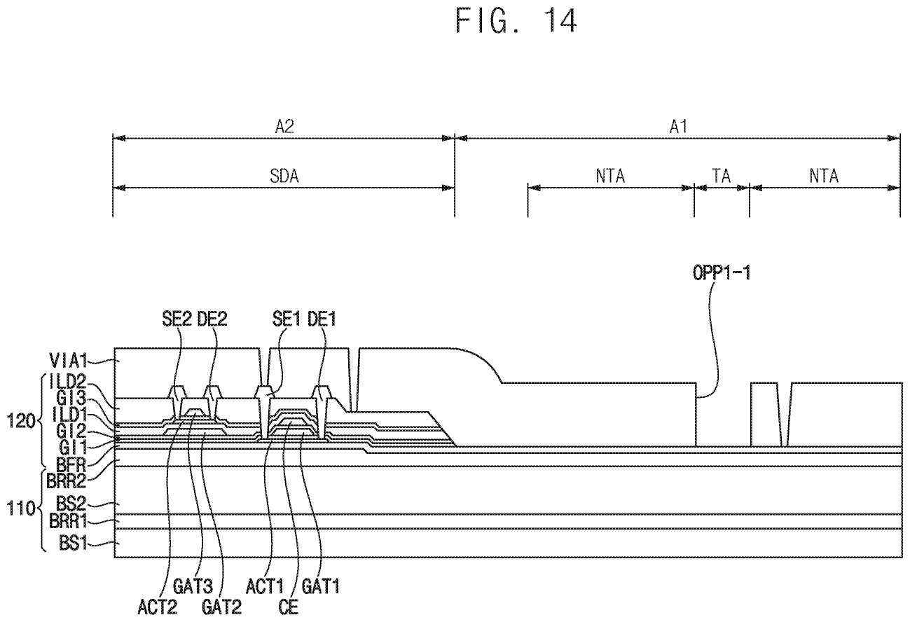

Further referring to FIG. 13, a first preliminary via insulating layer PVIA1 may be formed on the circuit element layer 120. By way of example, the first preliminary via insulating layer PVIA1 may be formed on the second interlayer insulating layer ILD2 and the buffer layer BFR to cover the first source electrode SE1, the first drain electrode DE1, the second source electrode SE2, and the second drain electrode DE2 in the first area A1 and the second area A2.

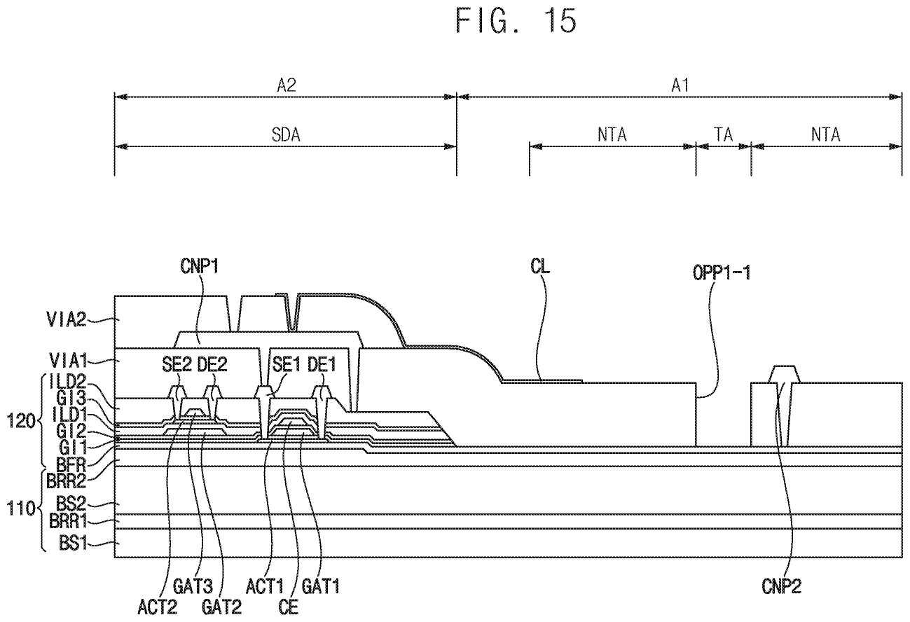

Further referring to FIG. 14, the first preliminary via insulating layer PVIA1 may be patterned. Accordingly, openings OPP1-1 overlapping the transmission area TA and contact holes may be formed in the first preliminary via insulating layer PVIA1. Therefore, after patterning, the first via insulating layer VIA1 including the opening OPP1-1 may be formed.

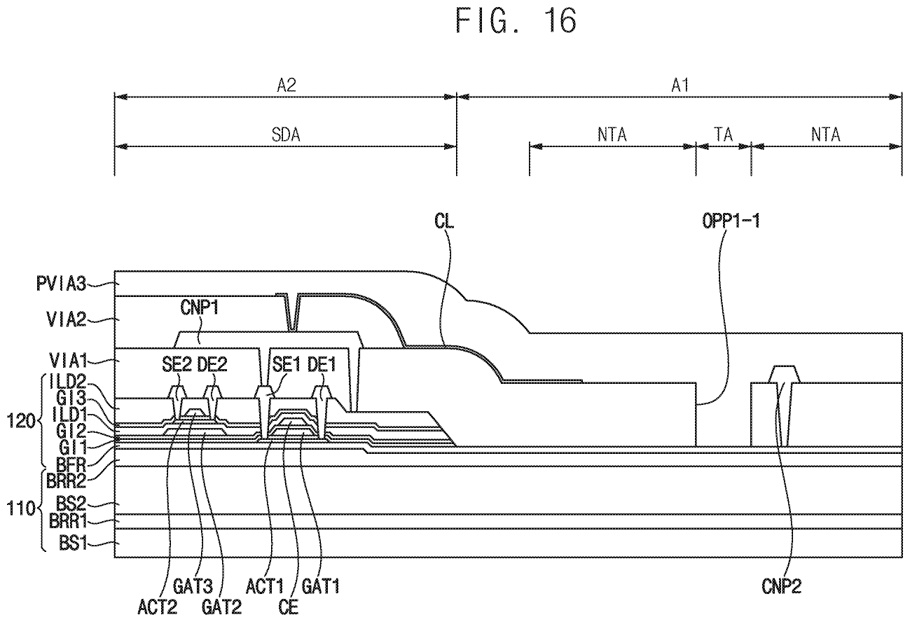

Referring further to FIG. 15, in the auxiliary display area SDA, a first connection electrode CNP1 may be formed on the first via insulating layer VIA1. In the first area A1, a second connection electrode CNP2 may be formed on the first via insulating layer VIA1.

In the auxiliary display area SDA, a second via insulating layer VIA2 may be formed on the first via insulating layer VIA1 to cover the first connection electrode CNP1.

A connection line CL may be formed on the second via insulating layer VIA2. The connection line CL may extend from the auxiliary display area SDA to the first area A1. The connection line CL may be formed to be connected to the first connection electrode CNP1.

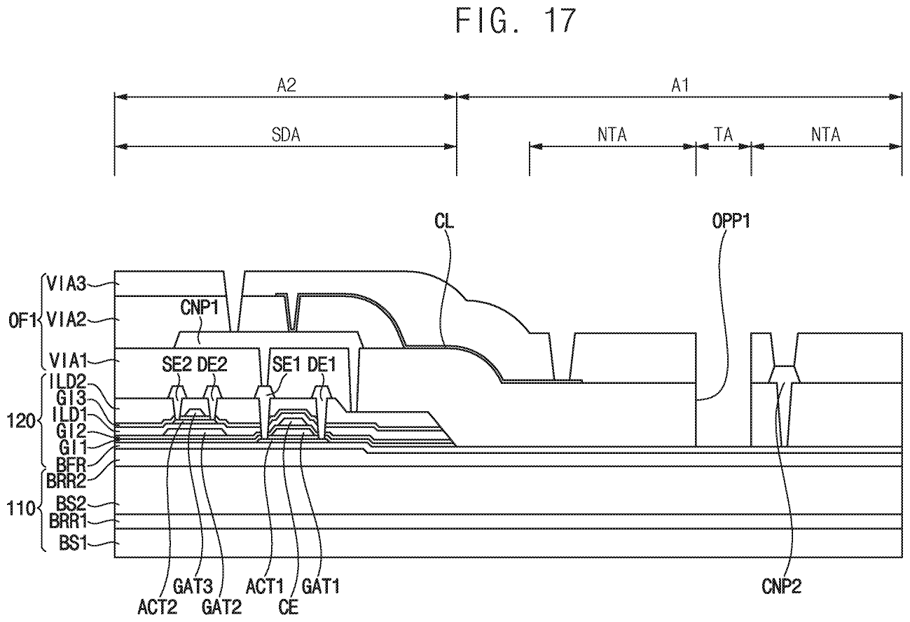

Referring further to FIG. 16, a third preliminary via insulating layer PVIA3 covering the connection line CL and the second connection electrode CNP2 in the second area A2 and the first area A1 may be formed.

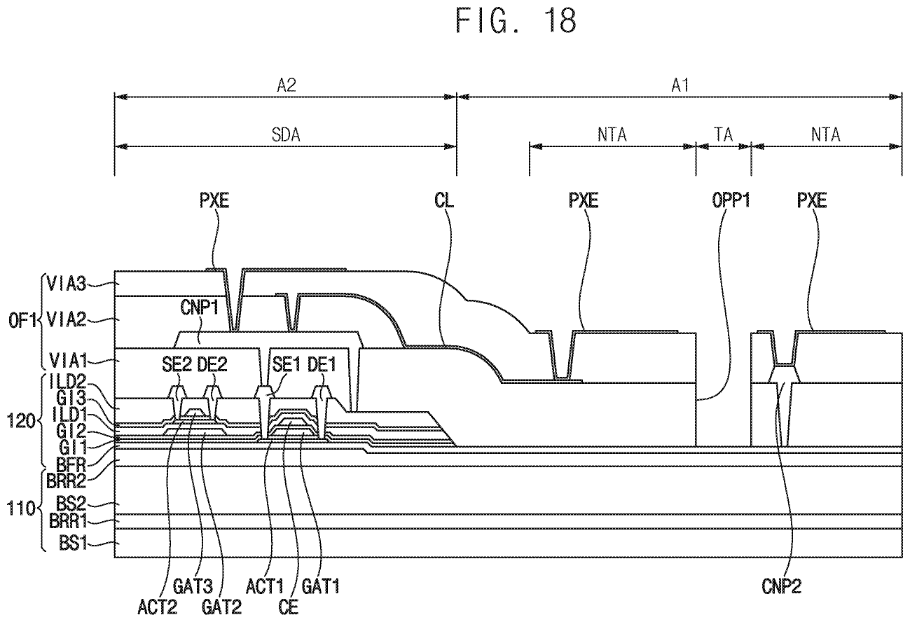

Further referring to FIG. 17, the third preliminary via insulating layer PVIA3 may be patterned. Accordingly, an opening overlapping the transmission area TA may be formed in the third preliminary via insulating layer PVIA3. Therefore, after patterning, a third via insulating layer VIA3 including the opening may be formed.

FIGS. 13, 14, 15, 16, and 17, the first via insulating layer VIA1 and the third via insulating layer VIA3 may form a first organic film OF1. Accordingly, a first opening OPP1 overlapping the transmission area TA may be formed in the first organic film OF1.

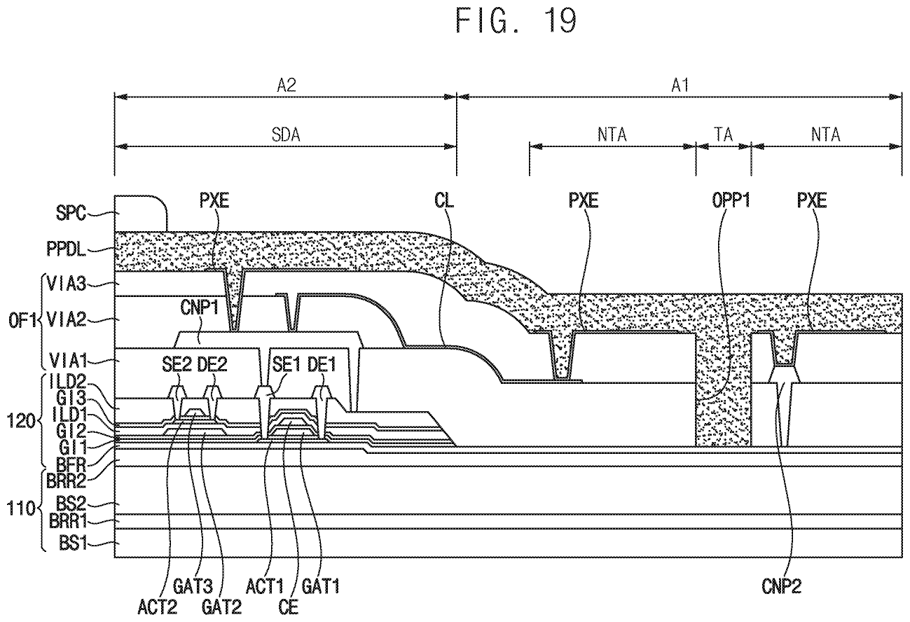

Further referring to FIG. 18, a pixel electrode PXE may be formed on the first organic film OF1. In the auxiliary display area SDA, the pixel electrode PXE may be connected to the first connection electrode CNP1. In the non-transmission area NTA of the first area A1, the pixel electrode PXE may be connected to the connection line CL or the second connection electrode CNP2.

Referring further to FIG. 19, a preliminary pixel defining layer PPDL may be formed on the third via insulating layer VIA3 to cover the pixel electrode PXE. A spacer SPC may be formed on the preliminary pixel defining layer PPDL.

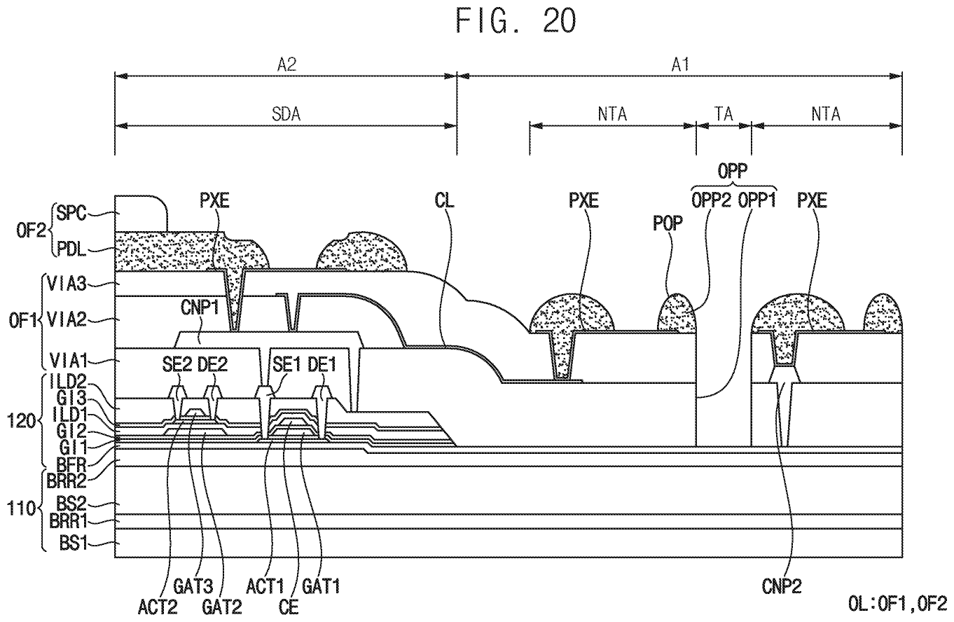

Further referring to FIG. 20, the preliminary pixel defining layer PPDL may be patterned. An opening overlapping the transmission area TA may be formed in the preliminary pixel defining layer PPDL. A pixel opening POP exposing a portion of the pixel electrode PXE may be formed in the preliminary pixel defining layer PPDL. Therefore, after patterning, a pixel defining layer PDL including the opening and the pixel opening POP may be formed.

Referring to FIGS. 19 and 20, the pixel defining layer PDL and the spacer SPC may form a second organic film OF2. Accordingly, a second opening OPP2 overlapping the transmission area TA and the pixel opening POP may be formed in the second organic film OF2.

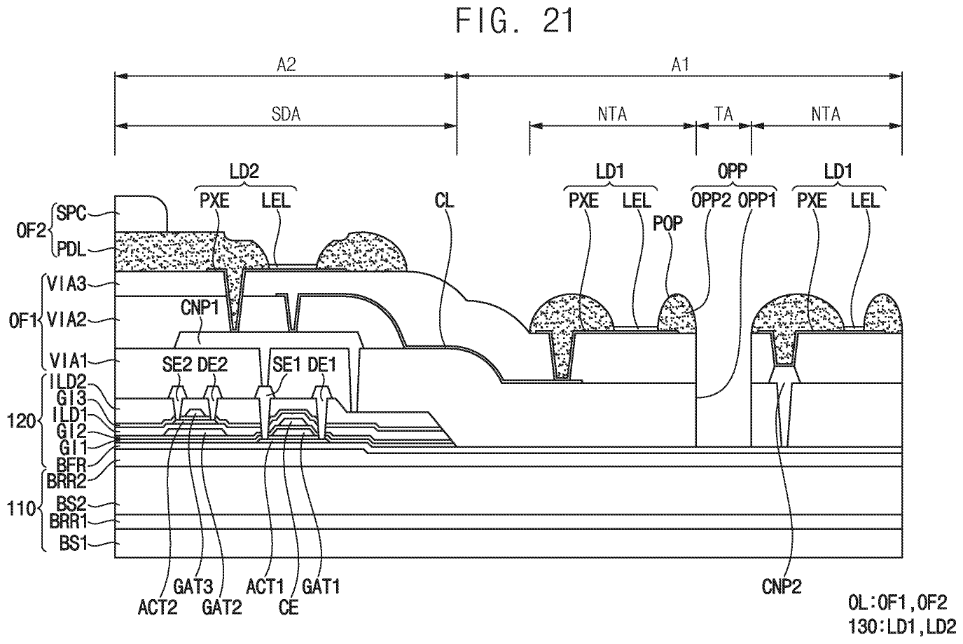

Referring to FIG. 21, a light emitting layer LEL may be formed on the pixel electrode PXE. The light emitting layer LEL may be formed in the pixel opening POP. A common electrode may be formed on the pixel defining layer PDL, the spacer SPC, and the third via insulating layer VIA3 to cover the light emitting layer LEL. Therefore, in the first area A1, the pixel electrode PXE, the light emitting layer LEL, and the common electrode may form first light emitting diodes LD1 overlapping the non-transmission area NTA. In the second area A2, the pixel electrode PXE, the light emitting layer LEL, and the common electrode may form second light emitting diodes LD2. Accordingly, the light emitting element layer 130 including the first light emitting diodes LD1 and the second light emitting diodes LD2 may be formed.

Referring to FIGS. 13, 14, 15, 16, 17, 18, 19, 20, and 21, the first organic film OF1 and the second organic film OF2 may form the organic layer OL. Accordingly, the opening OPP overlapping the transmission area TA may be formed in the organic layer OL. The opening OPP may be formed between the first light emitting diodes LD1. For example, the opening OPP may be spaced apart from the first light emitting diodes LD1 in the plan view.

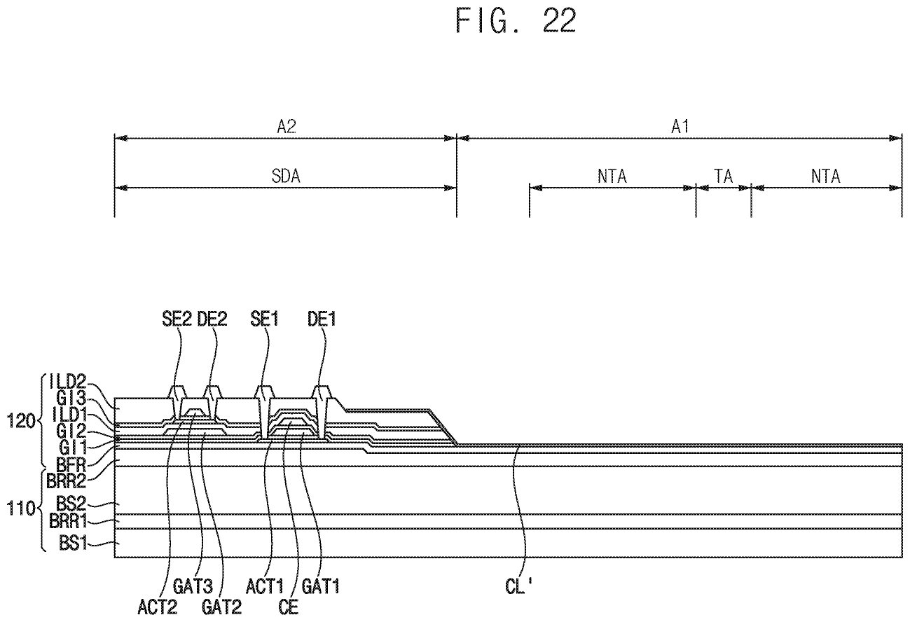

FIGS. 22, 23, and 24 are views illustrating a method of manufacturing another portion of a display device according to an embodiment.

The method of manufacturing the display device described with reference to FIGS. 22, 23, and 24 may be the method of manufacturing the display device of FIG. 6.

Referring further to FIG. 22, in the auxiliary display area SDA, a connection line CL′ may be additionally formed on the second interlayer insulating layer ILD2. In the first area A1, the connection line CL′ may be formed on the buffer layer BFR. The connection line CL′ may extend from the auxiliary display area SDA to the first area A1. The connection line CL′ may be connected to the circuit element layer 120.

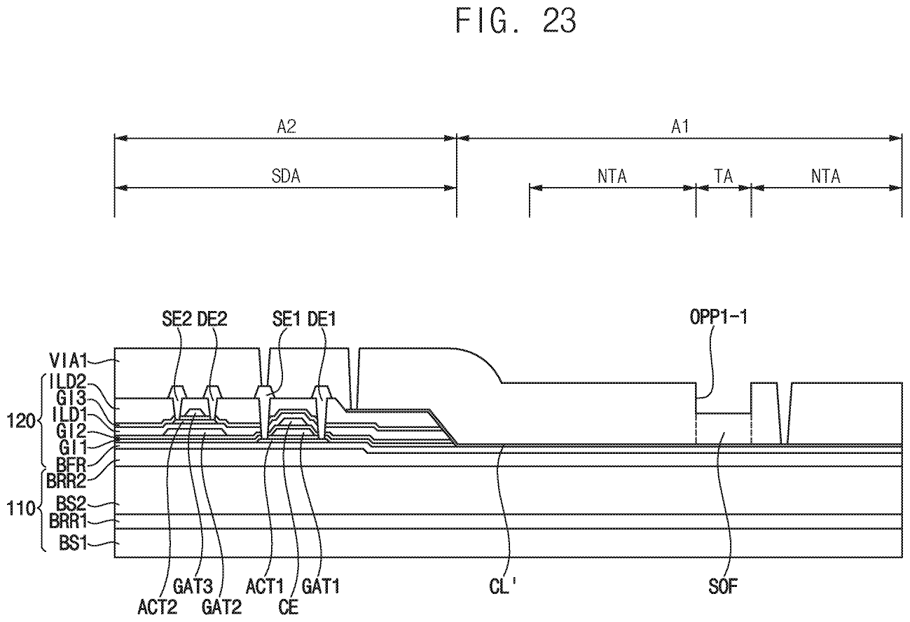

Further referring to FIG. 23, the first preliminary via insulating layer may be formed to cover the connection line CL′. The first preliminary via insulating layer may be patterned to form an opening OPP1-1 overlapping the transmission area TA in the first preliminary via insulating layer. In the transmission area TA, a sub-organic film SOF overlapping the connection line CL′ may be further formed in the first via insulating layer VIA1. Therefore, after patterning, the first via insulating layer VIA1 including the opening OPP1-1 and the sub-organic film SOF extending from the first via insulating layer VIA1 may be formed. The sub-organic film SOF may be formed to cover the connection line CL′ in the transmission area TA.

The sub-organic film SOF may be formed simultaneously with the first via insulating layer VIA1. The height of the sub-organic film SOF may be smaller than the height of the first via insulating layer VIA1 (see FIG. 6). For example, the sub-organic film SOF and the first organic film OF1 may be simultaneously formed using a halftone mask and may have different heights.

However, the disclosure is not limited thereto, and the sub-organic film SOF may extend from the third via insulating layer. The sub-organic film SOF may be formed simultaneously with the third via insulating layer, and the height of the sub organic layer SOF may be smaller than the height of the third via insulating layer.

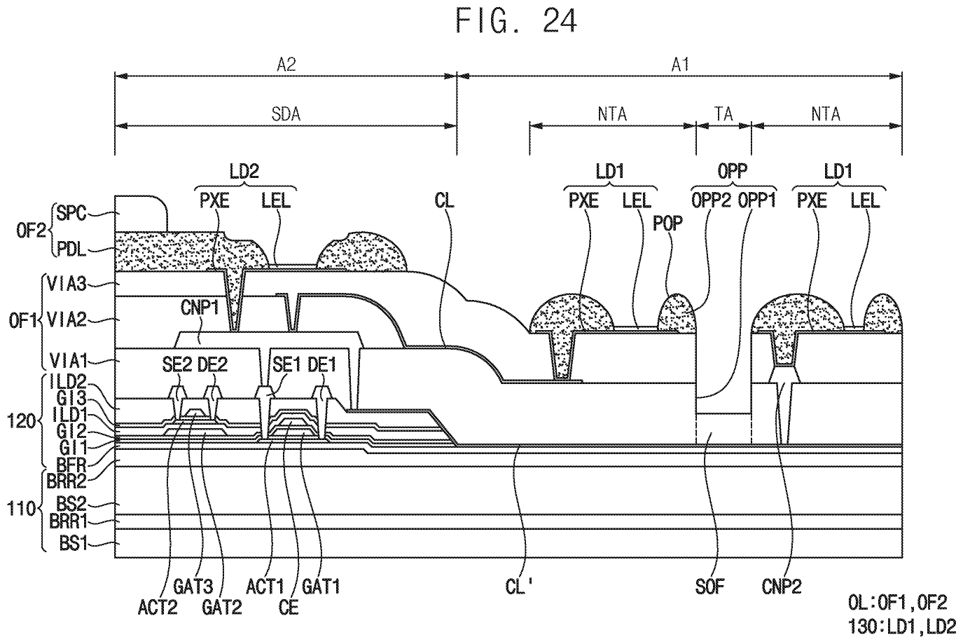

Referring further to FIG. 24, the connection line CL′ may be connected to the second connection electrode CNP2. Accordingly, the circuit element layer 120 and the light emitting element layer 130 may be connected through the connection line CL′.

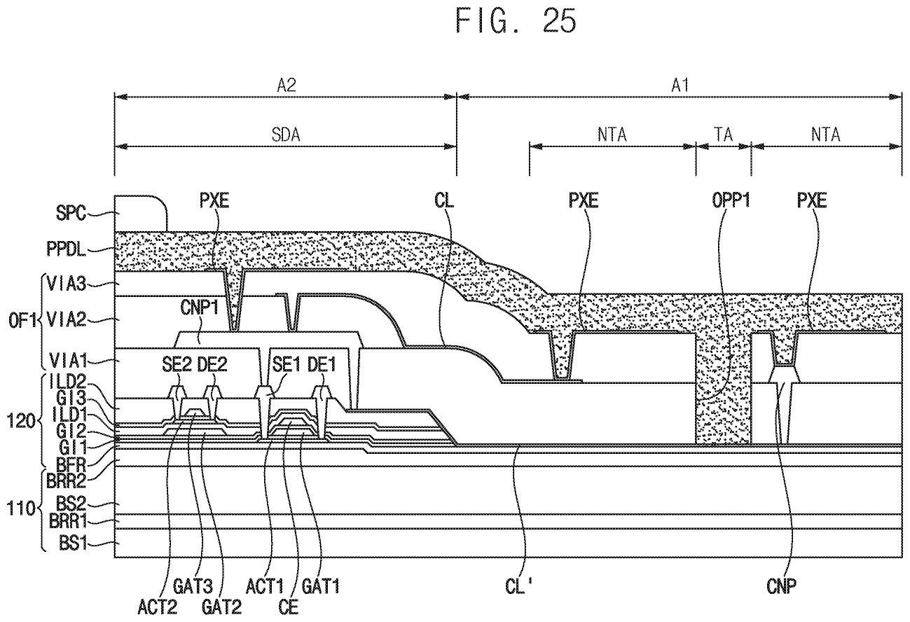

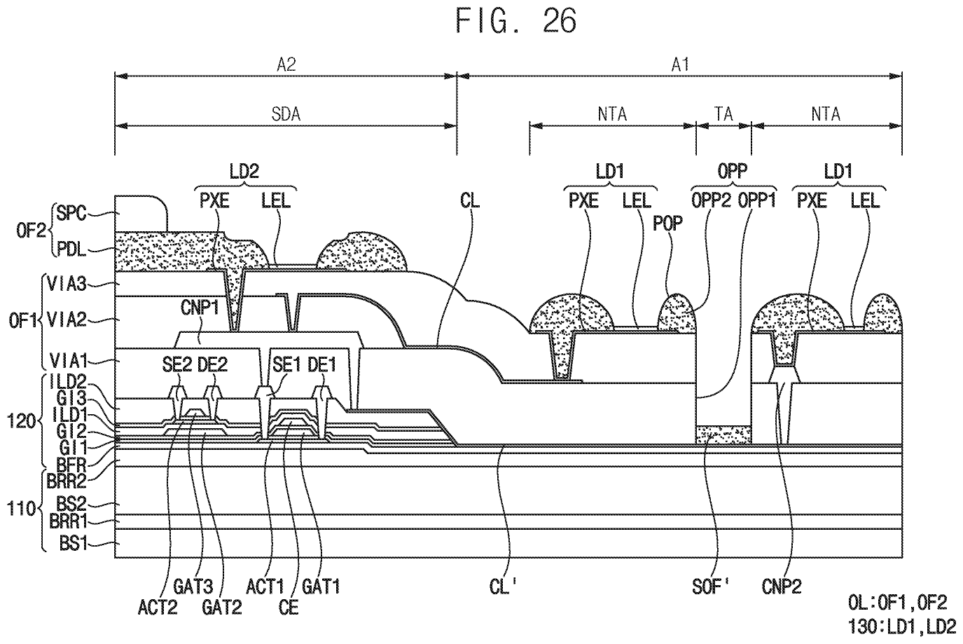

FIGS. 25 and 26 are views illustrating other examples of FIGS. 22, 23, and 24.

The method of manufacturing the display device described with reference to FIGS. 25 and 26 may be the method of manufacturing the display device of FIG. 7.

Referring to FIG. 25, a connection line CL′ may be additionally formed on the second interlayer insulating layer ILD2 in the auxiliary display area SDA. The connection line CL′ may extend from the auxiliary display area SDA to the first area A1.

In the second area A2 and the first area A1, the preliminary pixel defining layer PPDL may be formed to cover the connection line CL′.

Further referring to FIG. 26, the preliminary pixel defining layer PPDL may be patterned. Accordingly, a second opening OPP2 overlapping the transmission area TA may be formed in the preliminary pixel defining layer PPDL. In the transmission area TA, a sub-organic film SOF′ overlapping the connection line CL′ may be formed on the preliminary pixel defining layer PPDL. Therefore, after patterning, the pixel defining layer PDL including the second opening OPP2 and the sub-organic film SOF′ extending from the pixel defining layer PDL may be formed. The sub-organic film SOF′ may be formed to cover the connection line CL′ in the transmission area TA.

The sub-organic film SOF′ may be formed simultaneously with the pixel defining layer PDL. The height of the sub-organic film layer SOF′ may be smaller than the height of the pixel defining layer PDL (see FIG. 7). For example, the sub-organic film SOF′ and the pixel defining layer PDL may be simultaneously formed using a halftone mask and may have different heights.

In an embodiment, transmittance in the first area A1 of the display device 10 may be improved by patterning a preliminary organic film to form the opening OPP overlapping the transmission area TA. For example, since the organic layer OL is not disposed in the transmission area TA, reflection and absorption of light due to the organic layer OL may be minimized. Accordingly, display quality of the display device 10 may be improved.

By further forming the sub-organic film SOF on the connection line CL′ disposed in the transmission area TA using the halftone mask, unnecessary light emission due to the connection line CL′ may be prevented. Accordingly, display quality of the display device 10 may be improved.

Display devices according to embodiments can be applied to display devices included in computers, laptop computers, mobile phones, smart phones, smart pads, automobiles, PMPs, PDAs, MP3 players, and the like within the spirit and the scope of the disclosure.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the disclosure. Accordingly, all such modifications are intended to be included within the scope of the disclosure and as defined in the claims. Therefore, it is to be understood that the foregoing is illustrative of various embodiments and is not to be construed as limited to the embodiments disclosed, and that modifications to the disclosed embodiments, as well as other embodiments, are intended to be included within the scope of the appended claims.

What is claimed is:

1. A display device comprising:
a first area including a transmission area and a non-transmission area adjacent to the transmission area and a second area adjacent to the first area;
a circuit element layer disposed in the second area on a substrate;
a light emitting element layer disposed on the circuit element layer, electrically connected to the circuit element layer, and including first light emitting diodes disposed in the non-transmission area; and
an organic layer disposed on the circuit element layer, adjacent to the light emitting element layer, and including an opening overlapping the transmission area in a plan view and between the first light emitting diodes.

2. The display device of claim 1, wherein the opening of the organic layer is spaced apart from the first light emitting diodes in a plan view.

3. The display device of claim 1, wherein
the organic layer includes:
a first organic film disposed between the circuit element layer and the light emitting element layer, overlapping the second area and the non-transmission area in a plan view, and including a first opening overlapping the transmission area in a plan view; and
a second organic film disposed on the first organic film, overlapping the second area and the non-transmission area in a plan view, and including a second opening overlapping the transmission area in a plan view,
the first opening and the second opening overlap, in a plan view, and
the first opening and the second opening constitute the opening of the organic layer.

4. The display device of claim 3, wherein
the first organic film overlaps the first light emitting diodes in a plan view, and
the second organic film is adjacent to the first light emitting diodes.

5. The display device of claim 3, further comprising:
a connection line electrically connecting the circuit element layer and each of the first light emitting diodes; and
a sub-organic film covering the connection line in the transmission area.

6. The display device of claim 5, wherein a height of the sub-organic film is less than a sum of a height of the first organic film and a height of the second organic film.

7. The display device of claim 5, wherein
the sub-organic film and the first organic film include a same material, and
a height of the sub-organic film is less than a height of the first organic film.

8. The display device of claim 5, wherein
the sub-organic film and the second organic film include a same material, and
a height of the sub-organic film is less than a height of the second organic film.

9. The display device of claim 3, wherein the light emitting element layer further includes second light emitting diodes disposed on the circuit element layer and disposed in the second area.

10. The display device of claim 3, wherein each of the first light emitting diodes includes:
a pixel electrode; and
a light emitting layer disposed on the pixel electrode.

11. The display device of claim 10, wherein
the first organic film is disposed below the pixel electrode and overlaps the pixel electrode in a plan view,
the second organic film includes a pixel opening exposing a portion of the pixel electrode, and
the light emitting layer is disposed in the pixel opening.

12. A display device comprising:
a first area including a transmission area and a non-transmission area adjacent to the transmission area and a second area adjacent to the first area;
a circuit element layer disposed in the non-transmission area on a substrate;
a light emitting element layer disposed on the circuit element layer, electrically connected to the circuit element layer, and including light emitting diodes disposed in the non-transmission area; and
an organic layer disposed on the circuit element layer, adjacent to the light emitting element layer, and including an opening overlapping the transmission area in a plan view and between the light emitting diodes.

13. The display device of claim 12, wherein the opening of the organic layer does not overlap the light emitting diodes in a plan view.

14. The display device of claim 12, wherein the organic layer includes:
a first organic film disposed between the circuit element layer and the light emitting element layer, overlapping the second area and the non-transmission area in a plan view, and including a first opening overlapping the transmission area in a plan view; and
a second organic film disposed on the first organic film, overlapping the second area and the non-transmission area in a plan view, and including a second opening overlapping the transmission area in a plan view.

15. The display device of claim 14, wherein the first organic film overlaps the light emitting diodes in a plan view, and
the second organic film is adjacent to the light emitting diodes.

16. A method of manufacturing a display device, the method comprising:
forming a circuit element layer in a second area on a substrate, the display device including a first area including a transmission area and a non-transmission area adjacent to the transmission area, and the second area having a lower transmittance than a transmittance of the first area;
forming an organic layer on the circuit element layer;
forming a light emitting element layer including first light emitting diodes in the non-transmission area on the circuit element layer; and
forming an opening between the first light emitting diodes in the transmission area by patterning the organic layer.

17. The method of claim 16, wherein the forming of the light emitting element layer and the forming of the organic layer includes:
forming a first organic film on the circuit element layer;
forming a first opening overlapping the transmission area in the first organic film in a plan view;
forming a pixel electrode on the first organic film;
forming a second organic film on the pixel electrode;
forming a second opening overlapping the transmission area in a plan view and a pixel opening exposing a portion of the pixel electrode in the second organic film; and
forming a light emitting layer in the pixel opening.

18. The method of claim 17, further comprising:
forming a connection line electrically connected to the circuit element layer and the pixel electrode.

19. The method of claim 18, further comprising:
forming a sub-organic film overlapping the connection line in a plan view by patterning the first organic film.

20. The method of claim 19, wherein
the forming of the sub-organic film is performed simultaneously with the forming of the first organic film, and
a height of the sub-organic film is less than a height of the first organic film.

21. The method of claim 20, wherein the sub-organic film and the first organic film are formed by using a halftone mask.

22. The method of claim 18, further comprising:
forming a sub-organic film overlapping the connection line in a plan view by patterning the second organic film.

23. The method of claim 22, wherein
the forming of the sub-organic film is performed simultaneously with the forming of the second organic film, and
a height of the sub-organic film is smaller than a height of the second organic film.

24. The method of claim 23, wherein the sub-organic film and the second organic film are formed by using a halftone mask.
